(19) United States
(12) Patent Application Publication
(10) Pub. No.: US 2026/0024493 A1
(43) Pub. Date: Jan. 22, 2026

(54) DISPLAY DEVICE AND ELECTRONIC DEVICE HAVING THE SAME

(71) Applicant: Samsung Display Co., Ltd., Yongin-si (KR)

(72) Inventors: Hyang A PARK, Yongin-si (KR); Seo Young LIM, Yongin-si (KR); Go Een JEONG, Yongin-si (KR); Min Oh CHOI, Yongin-si (KR)

(21) Appl. No.: 19/205,736

(22) Filed: May 12, 2025

(30) Foreign Application Priority Data
Jul. 17, 2024 (KR) 10-2024-0094326

(51) Int. Cl. G09G 3/3233

(52) U.S. Cl. CPC G09G 3/3233; G09G 2360/142

(57) ABSTRACT

A display device includes a pixel including a pixel circuit and a light emitting element connected to the pixel circuit, the pixel circuit including a first transistor and a capacitor; a sensor including a sensor circuit, light receiving elements, and switching transistors connecting the light receiving elements to the sensor circuit, the sensor circuit including a sensor transistor; and control lines configured to control operations of the switching transistors, at least one of the control lines overlapping with at least one of the first transistor and the capacitor in a plan view.

### CROSS-REFERENCE TO RELATED APPLICATION

The present application claims priority to and the benefit of Korean Patent Application No. 10-2024-0094326, filed on Jul. 17, 2024, in the Korean Intellectual Property Office, the entire disclosure of which is incorporated herein by reference.

### BACKGROUND

### 1. Field

Aspects of embodiments of the present disclosure relate to a display device and an electronic device having the same.

### 2. Description of Related Art

With the development of information technologies, the importance of a display device which is a connection medium between a user and information increases. Accordingly, display devices such as a liquid crystal display device and an organic light emitting display device are increasingly used. In addition, a display device may sense a fingerprint of a user and perform a user authentication function, using a photo sensor.

The above information disclosed in this Background section is only for enhancement of understanding of the background of the invention and therefore it may contain information that does not form the prior art.

### SUMMARY

Aspects of some embodiments of the present disclosure are directed toa display device and an electronic device, which has improved resolution.

According to some embodiments of the disclosure, there is provided a display device including: a pixel including a pixel circuit and a light emitting element connected to the pixel circuit, the pixel circuit including a first transistor and a capacitor; a sensor including a sensor circuit, light receiving elements, and switching transistors connecting the light receiving elements to the sensor circuit, the sensor circuit including a sensor transistor; and control lines configured to control operations of the switching transistors, at least one of the control lines overlapping with at least one of the first transistor and the capacitor in a plan view.

In some embodiments, the control lines may extend in a first direction while transversing the pixel.

In some embodiments, the capacitor may include a capacitor electrode, and

wherein two or less insulating layers are interposed between the capacitor electrode and the control lines in a cross-sectional view.

In some embodiments, in a plan view, a partial section of at least one of the control lines may overlap with about 50% or more of the capacitor in a second direction, and the control lines may roughly extend in a first direction, wherein the second direction is perpendicular to the first direction.

In some embodiments, in a plan view, the partial section of the at least one of the control lines map completely overlap with the capacitor in the second direction.

In some embodiments, the switching transistors may include a first switching transistor configured to connect a first light receiving element to the sensor circuit in response to a first control signal of a first control line, and a second switching transistor configured to connect a second light receiving element to the sensor circuit in response to a second control signal of a second control line, and the first control line may overlap with the capacitor.

In some embodiments, in a plan view, the first control line may transvers the capacitor.

In some embodiments, the second control line may overlap with an edge portion of the capacitor.

In some embodiments, the display device may further include a data line configured to transmit a data signal; and a scan line configured to transmit a scan signal, wherein the pixel circuit further includes a second transistor configured to transfer the data signal to the first transistor in response to the scan signal, and wherein the first control line may overlap with the scan line.

In some embodiments, the second control line may not overlap with the capacitor.

In some embodiments, the display device may further include a data line configured to transmit a data signal; and a scan line configured to transmit a scan signal, wherein the pixel circuit further may include a second transistor configured to transfer the data signal to the first transistor in response to the scan signal, and wherein the first control line may overlap with the scan line.

In some embodiments, the switching transistors may include a first switching transistor configured to connect a first light receiving element to the sensor circuit in response to a first control signal of a first control line, and a second switching transistor configured to connect a second light receiving element to the sensor circuit in response to a second control signal of a second control line, and, in a plan view, the first control line and the second control line may transverse the capacitor.

In some embodiments, control signals applied to the control lines may change between a first voltage level and a second voltage level in only a blank period, and may have either the first voltage level or the second voltage level in an active period, and a valid data signal may be provided to the pixel in the active period, and the valid data signal may not be provided to the pixel in the blank period.

In some embodiments, the display device may further include a plurality of sensors including the sensor, wherein the control lines are commonly connected to all of the plurality of sensors.

In some embodiments, the first transistor of the pixel may include a silicon semiconductor, and the switching transistors of the sensor may include an oxide semiconductor.

In some embodiments, the light emitting element and the light receiving element may be at the same layer.

According to some embodiments of the disclosure, there is provided a display device including: a pixel including a pixel circuit and a light emitting element connected to the pixel circuit, the pixel circuit including a first transistor; a sensor including a sensor circuit, a light receiving element, and a switching transistor connecting the light receiving element to the sensor circuit, the sensor circuit including a sensor transistor; a scan line configured to control an operation of the first transistor; and a control line configured to control an operation of the switching transistor, wherein, in a plan view, the control line extends while transversing the pixel circuit, and overlaps with the scan line.

In some embodiments, in a cross-sectional view, three or fewer insulating layers may be interposed between the scan line and the control line.

In some embodiments, a control signal applied to the control line may

change between a first voltage level and a second voltage level in only a blank period, and may have either the first voltage level or the second voltage level in an active period, and a valid data signal may be provided to the pixel in the active period, and the valid data signal may not be provided to the pixel in the blank period.

According to some embodiments of the disclosure, there is provided an electronic device including: a display device configured to display an image, based on input image data; and a processor configured to provide the input image data to the display device, wherein the display device includes: a pixel including a pixel circuit and a light emitting element connected to the pixel circuit, the pixel circuit including a first transistor and a capacitor; a sensor including a sensor circuit, light receiving elements, and switching transistors connecting the light receiving elements to the sensor circuit, the sensor circuit including a sensor transistor; and control lines controlling operations of the switching transistors, and wherein, in a plan view, at least one of the control lines overlaps with at least one of the first transistor and the capacitor.

### BRIEF DESCRIPTION OF THE DRAWINGS

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the example embodiments to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a block diagram illustrating a display device according to some embodiments of the present disclosure.

FIG. 2 is a block diagram illustrating the display device shown in FIG. 1 according to some embodiments of the present disclosure.

FIG. 3 is a diagram illustrating an arrangement of backplane circuits of a display area of a display panel included in the display device shown in FIG. 2 according to some embodiments of the present disclosure.

FIG. 4 is a diagram illustrating the display area of the display panel included in the display device shown in FIG. 2 according to some embodiments of the present disclosure.

FIG. 5 is a circuit diagram illustrating a pixel and a photo sensor, which are included in the display area shown in FIG. 4, according to some embodiments of the present disclosure.

FIG. 6 is a waveform diagram illustrating operations of the pixel and the photo sensor, which are shown in FIG. 5, according to some embodiments of the present disclosure.

FIG. 7 is a waveform diagram illustrating operations of the pixel and the photo sensor, which are shown in FIG. 5, according to some embodiments of the present disclosure.

FIGS. 8, 9A, 9B, and 10 are plan views illustrating the display area shown in FIG. 4 according to some embodiments of the present disclosure.

FIG. 11 is a cross-sectional view illustrating the display area shown in FIG. 4 according to some embodiments of the present disclosure.

FIGS. 12 and 13 are plan views illustrating the display area shown in FIG. 4 according to some other embodiments of the present disclosure.

FIG. 14 is a plan view illustrating the display area shown in FIG. 4 according to still some other embodiments of the present disclosure.

FIG. 15 is a cross-sectional view illustrating the display area shown in FIG. 4 according to still some other embodiments of the present disclosure.

FIG. 16 is a block diagram of an electronic device according to some embodiments of the present disclosure.

FIG. 17 shows schematic views of various embodiments of an electronic device.

### DETAILED DESCRIPTION

Hereinafter, embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

When a certain embodiment may be implemented differently, a specific process order may be different from the described order. For example, two consecutively described processes may be performed at the same or substantially at the same time, or may be performed in an order opposite to the described order.

In the drawings, the relative sizes, thicknesses, and ratios of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

In the figures, the x-axis, the y-axis, and the z-axis are not limited to three axes of the rectangular coordinate system, and may be interpreted in a broader sense. For example, the x-axis, the y-axis, and the z-axis may be perpendicular to or substantially perpendicular to one another, or may represent different directions from each other that are not perpendicular to one another.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. Similarly, when a layer, an area, or an element is referred to as being “electrically connected” to another layer, area, or element, it may be directly electrically connected to the other layer, area, or element, and/or may be indirectly electrically connected with one or more intervening layers, areas, or elements therebetween. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” “includes,” “including,” “has,” “have,” and “having,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression “A and/or B” denotes A, B, or A and B. Expressions such as “at least one of,” when preceding a list of elements, modify the entire list of elements and do not modify the individual elements of the list. For example, the expression “at least one of a, b, or c,” “at least one of a, b, and c,” and “at least one selected from the group consisting of a, b, and c” indicates only a, only b, only c, both a and b, both a and c, both b and c, all of a, b, and c, or variations thereof.

As used herein, the term “substantially,” “about,” and similar terms are used as terms of approximation and not as terms of degree, and are intended to account for the inherent variations in measured or calculated values that would be recognized by those of ordinary skill in the art. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively.

The electronic or electric devices and/or any other relevant devices or components according to embodiments of the present disclosure described herein may be implemented utilizing any suitable hardware, firmware (e.g. an application-specific integrated circuit), software, or a combination of software, firmware, and hardware. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate. Further, the various components of these devices may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the spirit and scope of the example embodiments of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

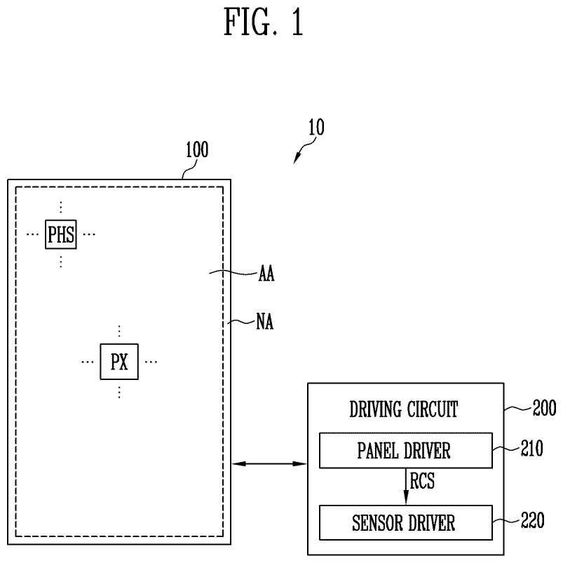

FIG. 1 is a block diagram illustrating a display device according to some embodiments of the present disclosure.

Referring to FIG. 1, the display device 10 may include a display panel 100 and a driving circuit 200. In some embodiments, the driving circuit 200 may include a panel driver 210 and a sensor driver 220.

The display device 10 may be implemented as a self-luminous display device including a plurality of self-luminous elements. For example, the display device 10 may be an organic light emitting display device including an organic light emitting element. However, this is merely illustrative, and the display device 10 may be implemented as a display device including an inorganic light emitting element, a display device including light emitting elements configured with a combination of an inorganic material and an organic material, a display device which displays an image, using a quantum dot, or the like.

The display device 10 may be a flat panel display device, a flexible display device, a curved display device, a foldable display device, a bendable display device, a rollable display device, or the like. Also, the display device 10 may be applied to a transparent display device, a head-mounted display device, a wearable display device, and the like.

The display panel 100 may include a display area AA and a non-display area NA. The display area AA may be an area in which at least one pixel PX is provided. The pixel PX may be referred to as a sub-pixel or a light emitting pixel. The pixel PX may include at least one light emitting element. For example, the light emitting element may include a light emitting layer (e.g., an organic light emitting layer). A portion at which light is emitted by the light emitting element may be defined as an emission area. The display device 10 may drive the pixel PX, thereby displaying an image in the display area AA.

The non-display area NA may be an area provided at the periphery of the display area AA. In some embodiments, the non-display area NA may inclusively mean the other area except the display area AA on the display panel 100. For example, the non-display area NA may include a line area, a pad area, various dummy areas, and the like.

In some embodiments, at least one photo sensor PHS (or sensor) may be included in the display area AA. The photo sensor PHS may be referred to as a sensor pixel. The photo sensor PHS may include a light receiving element including a light receiving layer. The light receiving layer of the light receiving element may be disposed in the same layer as the light emitting layer of the light emitting element in the display area AA, and be spaced apart from the light emitting element on a plane (e.g., in a plan view).

In some embodiments, a plurality of photo sensors PHS may be distributed while being spaced apart from each other throughout the entire area of the display area AA. However, this is merely illustrative. Only a portion of the display area AA may be set as a set sensing area (e.g., a preset or predetermined sensing area), and photo sensors PHS may be provided in the corresponding sensing area. In addition, the photo sensor PHS may be included in at least a portion of the non-display area NA.

In some embodiments, the photo sensor PHS may sense that light output from a light source (e.g., the light emitting element of the pixel PX) is reflected by an external object (e.g., a finger of a user, or the like). For example, a fingerprint of the user may be sensed through the photo sensor PHS. Hereinafter, a case where the photo sensor PHS is used for fingerprint sensing will be described as an example. However, in some embodiments, the photo sensor PHS may sense various biometric information, such as an iris or a vein.

The driving circuit 200 may include the panel driver 210 and the sensor driver 220. The display device 10 may include the panel driver 210 and the sensor driver 220. For example, the panel driver 210 and the sensor driver 220 may be implemented as integrated circuits independent from each other, or the driving circuit 200 may be implemented as one integrated circuit. For example, at least a portion of the sensor driver 220 may be included in the panel driver 210, or operate in connection with the panel driver 210.

The panel driver 210 may scan the pixel PX of the display area AA, and supply, to the pixel PX, a data signal corresponding to image data (or an image). The display panel 100 may display an image corresponding to the data signal.

In some embodiments, the panel driver 210 may supply a driving signal for photo sensing (e.g., fingerprint sensing) to the pixel PX. The driving signal may be provided to allow the pixel PX to emit light, thereby operating as a light source for the photo sensor PHS. In some embodiments, the panel driver 210 may supply the driving signal for photo sensing and/or another driving signal to the photo sensor PHS. However, this is merely illustrative, and driving signals for photo sensing may be provided by the sensor driver 220.

The sensor driver 220 may detect biometric information, such as a finger of the user, based on a sensing signal received from the photo sensor PHS. In some embodiments, the sensor driver 220 may supply the driving signals to the photo sensor PHS and/or the pixel PX.

In some embodiments, the panel driver 210 may provide a readout control signal RCS to the sensor driver 220, and the sensor driver 220 may read out (or sample) a sensing signal in connection with the panel driver 210, based on the readout control signal RCS. For example, the sensor driver 220 may read out or sample the sensing signal in at least one pixel row (or horizontal line) unit in response to the readout control signal RCS.

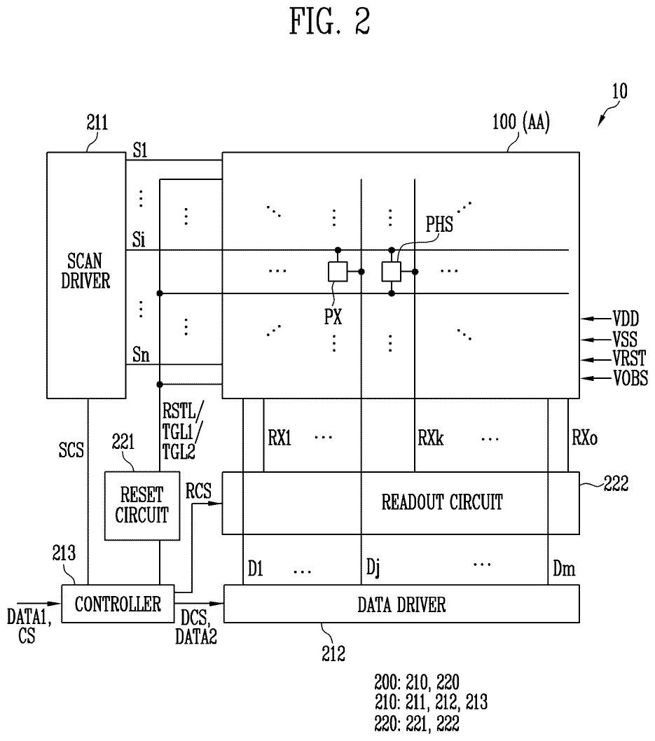

FIG. 2 is a block diagram illustrating the display device shown in FIG. 1 according to some embodiments of the present disclosure.

Referring to FIGS. 1 and 2, a display panel 100 may include signal lines, pixels PX, and photo sensors PHS. The signal lines may include scan lines S1 to Sn, data lines D1 to Dm, readout lines RX1 to RXo, and a reset control line RSTL (or reset line), a first control line TGL1, and a second control line TGL2. Each of n, m, and o may be a natural number.

The pixels PX may be disposed or located in areas (e.g., pixel areas) partitioned by the scan lines S1 to Sn and the data lines D1 to Dm. The photo sensors PHS may be disposed or located in areas partitioned by the scan lines S1 to Sn and the readout lines RX1 to RXo. The pixels PX and the photo sensors PHS may be arranged in a two-dimensional array in a display area AA of the display panel 100, but the present disclosure is not limited thereto.

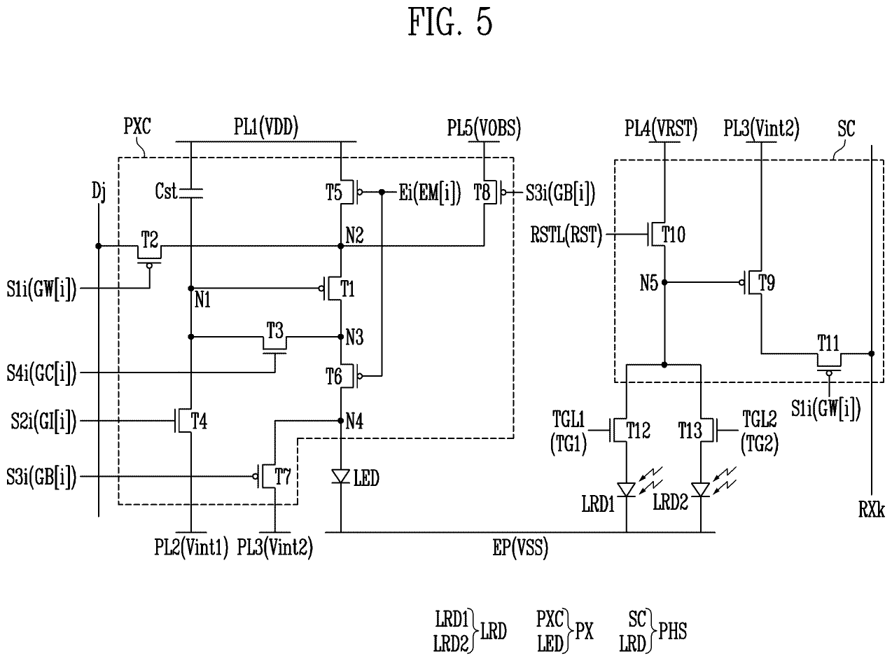

The pixel PX may be electrically connected to at least one of the scan lines S1 to Sn and at least one of the data lines D1 to Dm. The photo sensor PHS may be electrically connected to one of the scan lines S1 to Sn, one of the readout lines RX1 to RXo, the reset control line RSTL, the first control line TGL1, and the second control line TGL2. A connection configuration between the pixel PX, the photo sensor PHS, and the signal lines will be described later with reference to FIG. 5.

Power voltages VDD, VSS, VRST, and VOBS for driving of the pixel PX and the photo sensor PHS may be provided to the display panel 100. The power voltages VDD, VSS, VRST, and VOBS may be supplied from a power supply. The power supply may be implemented as a Power Management integrated circuit (PMIC).

A driving circuit 200 may include a scan driver 211 (or gate driver), a data driver 212 (or source driver), a controller 213 (e.g., timing controller, or second processor), a reset circuit 221 (or reset unit), and a readout circuit 222 (or readout unit). For example, the scan driver 211, the data driver 212, and the controller 213 may be included in a panel driver 210, and the reset circuit 221 and the readout circuit 222 may be included in a sensor driver 220. However, the present disclosure is not limited thereto. For example, the reset circuit 221 may be included in the panel driver 210.

The scan driver 211 may be electrically connected to the pixels PX and the photo sensors PHS through the scan lines S1 to Sn. The scan driver 211 may generate scan signals, based on a scan control signal SCS (or gate control signal), and supply the scan signals to the scan lines S1 to Sn. The scan control signal SCS may include a start signal, clock signals, and the like, and be provided from the controller 213 to the scan driver 211. For example, the scan driver 211 may be implemented as a shift register which may generate and may output scan signals by sequentially shifting the start signal in a pulse form, using the clock signals. For example, the scan driver 211 may selectively drive the pixels PX and the photo sensors PHS while scanning the display panel 100.

The scan driver 211 may be formed together with the pixels PX of the display panel 100. However, the scan driver 211 is not limited thereto. For example, the scan driver 211 may be implemented as an integrated circuit.

A pixel PX selectively driven by the scan driver 211 may emit light with a luminance corresponding to a data signal provided to a data line. For example, a pixel PX selectively driven through an ith scan line Si may emit light with a luminance corresponding to a data line provided to a jth data line Dj (each of i and j is a natural number). A photo sensor PHS selectively driven by the scan driver 211 may output, to a readout line, an electrical signal (i.e., a sensing signal, e.g., a current/voltage) corresponding to sensed light. For example, a photo sensor PHS selectively driven through the ith scan line Si may output, to a kth readout line RXk, an electrical signal corresponding to sensed light (k is a natural number).

The data driver 212 may generate a data signal (or data voltage), based on image data DATA2 and a data control signal DCS, which are provided from the controller 213, and supply the data signal to the display panel 100 (or the pixels PX) through the data lines D1 to Dm. The data control signal DCS may be a signal for controlling an operation of the data driver 212, and include a data enable signal (or load signal) instructing an output of a valid data signal, a horizontal start signal, a data clock signal, and the like. For example, the data driver 212 may include a shift register which generates a sampling signal by shifting the horizontal start signal in synchronization with the data clock signal, a latch which latches the image data DATA2 in response to the sampling signal, a digital-analog converter (or decoder) which converts the latched image data (e.g., data in a digital form) into a data signal in an analog form, and a buffer (or amplifier) which outputs the data signal to a corresponding data line (e.g., the jth data line Dj).

The controller 213 may receive input image data DATA1 and a control signal CS from an external device (e.g., a graphic processor, an application processor, a first processor, or the like), generate the scan control signal SCS and the data control signal DCS, based on the control signal CS, and generate the image data DATA2 by converting the input image data DATA1. The control signal CS may include a vertical synchronization signal, a horizontal synchronization signal, a reference clock signal, and the like. The vertical synchronization signal may represent a start of frame data (i.e., data corresponding to a frame period in which one frame image is displayed), and the horizontal synchronization signal may represent a start of a data row (i.e., one data row among a plurality of data rows included in frame data). The controller 213 may convert the input image data DATA1 into the image data DATA2 having a format corresponding to a pixel arrangement in the display panel 100.

Also, the controller 213 may generate a reset control signal and a readout control signal RCS, based on the control signal CS.

The reset circuit 221 may be connected to the photo sensors PHS provided in the display panel 100 through the reset control line RSTL. For example, the reset circuit 221 may be commonly connected to all the photo sensors PHS provided in the display panel 100 through one reset control line RSTL. The reset circuit 221 may concurrently (e.g., simultaneously or substantially simultaneously) provide a reset signal (or reset control signal) to all the photo sensors PHS through the reset control line RSTL in response to the reset control signal. The reset signal may be a control signal for providing a reset voltage VRST. Because the reset signal may be concurrently (e.g., simultaneously) provided to all the photo sensors PHS, the reset signal may be referred to as a global reset signal. However, the reset circuit 221 is not limited thereto. For example, the reset circuit 221 may be implemented similarly to the scan driver 211, to sequentially provide the reset signal to the photo sensors PHS.

The reset circuit 221 may be connected to the photo sensors PHS provided in the display panel 100 through each of the first control line TGL1 and the second control line TGL2. For example, the reset circuit 221 may be commonly connected to all the photo sensors PHS provided in the display panel 100 through each of the first control line TGL1 and the second control line TGL2. The reset circuit 221 may provide a first control signal to all the photo sensors PHS through the first control line TGL1, or may provide a second control signal to all the photo sensors PHS through the second control line TGL2. Although it will be described later with reference to FIG. 5, the photo sensor PHS may include two light receiving elements. The photo sensor PHS may select or use one of the two light receiving elements in response to the first control signal, or select or use the other of the two light receiving elements in response to the second control signal.

The readout circuit 222 may receive a sensing signal from the photo sensor PHS through the readout lines RX1 to RXo, and perform signal processing on the sensing signal. For example, the readout circuit 222 may convert the sensing signal in an analog form into a signal (or digital value) in a digital form.

Read-out sensing signals may be provided as one sensing data (or biometric information) to an external device (e.g., an application processor), and biometric authentication (e.g., fingerprint authentication) may be performed based on the sensing data. Alternatively, the read-out sensing signals may be provided to the controller 213, and biometric authentication may be performed in the controller 213.

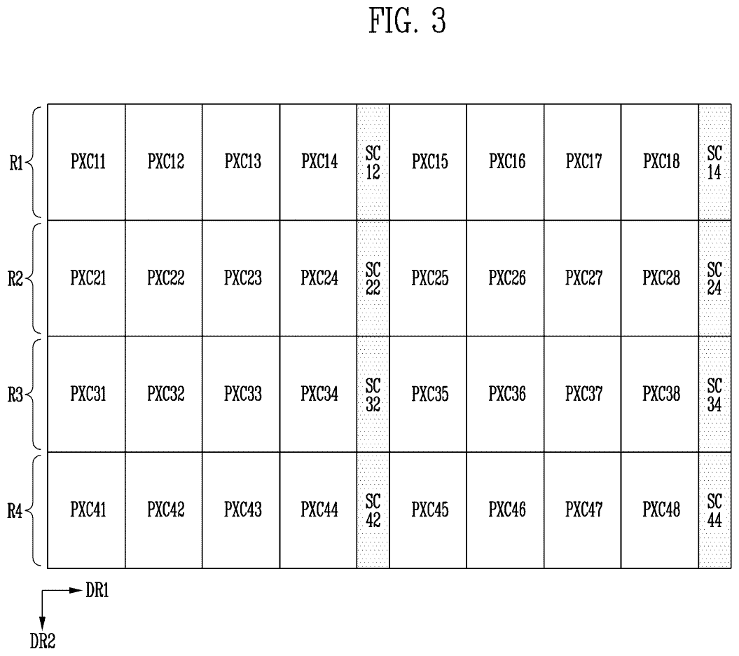

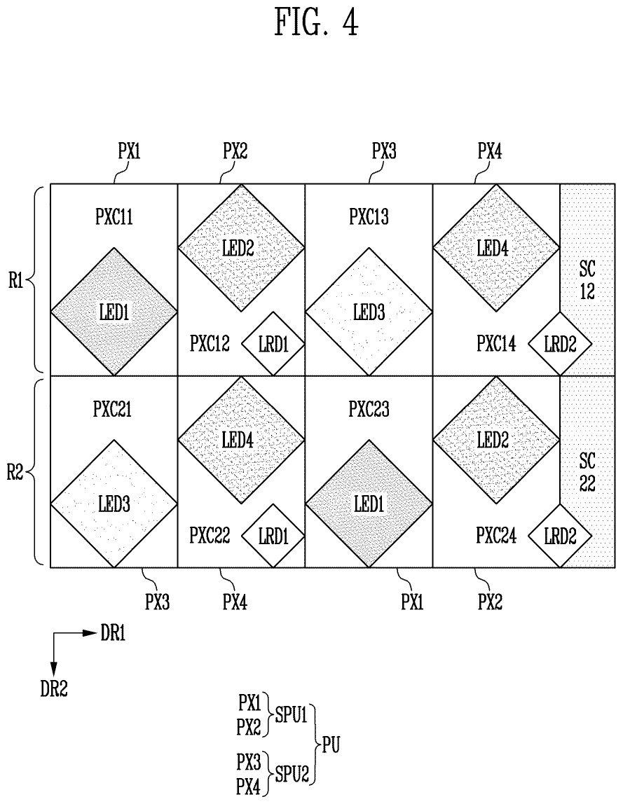

FIG. 3 is a diagram illustrating an arrangement of backplane circuits of the display area of the display panel included in the display device shown in FIG. 2 according to some embodiments of the present disclosure. FIG. 4 is a diagram illustrating the display area of the display panel included in the display device shown in FIG. 2 according to some embodiments of the present disclosure.

Referring to FIGS. 1 to 4, pixels PX1 to PX4 and a plurality of photo sensors PHS may be disposed in the display area AA of the display panel 100.

The display area AA may be divided into pixel rows R1 to R4. Each of the pixel rows R1 to R4 may extend in a first direction DR1, and be arranged in a second direction DR2. Each of the pixel rows R1 to R4 may include pixels PX1 to PX4. Each of the pixels PX1 to PX4 may include one of pixel circuits PXC11 to PXC48 and one of light emitting elements LED1 to LED4.

In some embodiments, a first pixel PX1, a second pixel PX2, and a third pixel PX3 may emit first color light, second color light, and third color light, respectively. The first color light, the second color light, and the third color light may be different color lights, and each of the first color light, the second color light, and the third color light may be one of red, green, and blue. In some embodiments, a fourth pixel PX4 may emit the same color light as the second pixel PX2. For example, a first light emitting element LED1 may emit the first color light, a second light emitting element LED2 and a fourth light emitting element LED4 may emit the second color light, and a third light emitting element LED3 may emit the third color light.

In FIG. 4, each of the light emitting elements LED1 to LED4 may be understood as an emission area corresponding to a light emitting layer. However, this is for convenience of description, and the color of light emitted by each of the light emitting elements LED1 to LED4, and the position, area, shape, and the like of each of the light emitting elements LED1 to LED4 are not be limited thereto.

In some embodiments, pixels PX1 to PX4 may be arranged with respect to the first direction DR1 in an order of a first pixel PX1 emitting red light, a second pixel PX2 emitting green light, a third pixel PX3 emitting blue light, and a fourth pixel PX4 emitting green light on each of odd-numbered pixel rows including a first pixel row R1 (or first horizontal line) and a third pixel row R3 (or third horizontal line).

Pixels PX1 to PX4 may be arranged with respect to the first direction DR1 in an order of a third pixel PX3, a fourth pixel PX4, a first pixel PX1, and a second sub-pixel SPX2 on each of even-numbered pixel rows including a second pixel row R2 (or second horizontal line) and a fourth pixel row R4 (or fourth horizontal line).

In some embodiments, the first pixel PX1 and the second pixel PX2 may constitute a first sub-pixel unit SPU1, and the third pixel PX3 and the fourth pixel PX4 may constitute a second sub-pixel unit SPU2. Therefore, the first sub-pixel unit SPU1 and the second sub-pixel unit SPU2 may be alternately disposed on the odd-numbered pixel rows R1 and R3, and the second sub-pixel unit SPU2 and the first sub-pixel unit SPU2 may be alternately disposed on the even-numbered pixel rows R2 and R4 in a pattern opposite to the pattern in which the first sub-pixel unit SPU1 and the second sub-pixel unit SPU2 are alternately disposed on the odd-numbered pixel rows R1 and R3.

It may be understood that set (e.g., preset or predetermined) first and second sub-pixel units SPU1 and SPU2 adjacent to each other constitute one pixel unit PU. For example, FIG. 4 illustrates a pixel unit PU of each of the first pixel row R1 and the second pixel row R2. However, this is merely illustrative, and the arrangement of pixels is not limited thereto.

Pixel circuits PXC11 to PXC14 respectively correspond to pixels PX1 to PX4. Pixel circuits PXC11 to PXC18 of the first pixel row R1 may be arranged along the first direction DR1 on the first pixel row R1. Pixel circuits PXC21 to PXC28 of the second pixel row R2 may be arranged along the first direction DR1 on the second pixel row R2. Similarly, pixel circuits PXC31 to PXC38 and PXC41 to PXC48 of the third and fourth pixel rows R3 and R4 may be arranged along the first direction DR1 on the third and fourth pixel rows R3 and R4.

In FIG. 3, first, second, third, and fourth pixel circuits PXC11, PXC12, PXC13, and PXC14 of the first pixel row R1 may be included in one pixel unit PU, and fifth, sixth, seventh, and eighth pixel circuits PXC15, PXC16, PXC17, and PXC18 of the first pixel row R1 may be included in another pixel unit PU.

Similarly to this, first to fourth pixel circuits PXC21 to PXC24 of the second pixel row R2, fifth to eighth pixel circuits PXC25 to PXC28 of the second pixel row R2, first to fourth pixel circuits PXC31 to PXC34 of the third pixel row R3, fifth to eighth pixel circuits PXC35 to PXC38 of the third pixel row R3, first to fourth pixel circuits PXC41 to PXC44 of the fourth pixel row R4, and fifth to eighth pixel circuits PXC45 to PXC48 of the fourth pixel row R4 each may also be included in different pixel units PU.

In some embodiments, each of the pixel rows R1 to R4 may include light receiving elements LRD1 to LRD4. In FIG. 4, each of the light receiving elements LRD1 to LRD4 may be understood as a light receiving area corresponding to a light receiving layer. However, this is merely for convenience of description, and the position, area, shape, and the like of each of the light receiving elements LRD1 to LRD4 are not limited thereto.

Light receiving elements LRD1 and LRD2 of the first pixel row R1 may overlap with at least portions of the pixel circuits PXC11 to PXC14 of the first pixel row R1 and a second sensor circuit SC12 of the first pixel row R1, respectively. Light receiving elements LRD1 and LRD2 of the second pixel row R2 may overlap with at least portions of the pixel circuits PXC21 to PXC24 of the second pixel row R2 and a second sensor circuit SC22 of the second pixel row R2, respectively.

In some embodiments, on the first pixel row R1, a first light receiving element LRD1 may overlap with at least a portion of a second pixel circuit PXC12 of the first pixel row R1, and a second light receiving element LRD2 may overlap with at least a portion of the second sensor circuit SC12 of the first pixel row R1. In the second pixel row R2, a first light receiving element LRD1 may overlap with at least a portion of a second pixel circuit PXC22 of the second pixel row R2, and a second light receiving element LRD2 may overlap with at least a portion of the second sensor circuit SC22 of the second pixel row R2.

In some embodiments, each of the sensor circuits SC12 and SC22 may be connected to at least two light receiving elements. For example, the second sensor circuit SC12 of the first pixel row R1 may be connected to the first light receiving element LRD1 and the second light receiving element LRD2 of the first pixel row R1, and the second sensor circuit SC12, the first light receiving element LRD1, and the second light receiving element LRD2 of the first pixel row R1 may constitute one photo sensor PHS. Similarly, the second sensor circuit SC22 of the second pixel row R2 may be connected to the first light receiving element LRD1 and the second light receiving element LRD2 of the second pixel row R2, and the second sensor circuit SC22, the first light receiving element LRD1, and the second light receiving element LRD2 of the second pixel row R2 may constitute one photo sensor PHS. However, the present disclosure is not limited thereto. For example, each of the sensor circuits SC12 and SC22 may be connected to three or more light receiving elements. In some embodiments, the sensor circuits SC12 and SC22 may be provided one-to-one corresponding to the light receiving elements LRD1 and LRD2. In some embodiments, the sensor circuits SC12 and SC22 may be provided corresponding to two or more of the light receiving elements LRD1 and LRD2, so that the area occupied by the sensor circuits SC12 and SC22 can be decreased, and the resolution of the display device 10 can be improved.

Referring to FIG. 3, each of the sensor circuits SC12 and SC22 may be disposed corresponding to a pixel unit PU. At least one pixel unit PU may be disposed between the sensor circuits SC12 and SC22. For example, on the first pixel row R1, four pixel circuits (e.g., PXC15 to PXC18) may be disposed between the second sensor circuit SC12 and the fourth sensor circuit SC14.

FIG. 5 is a circuit diagram illustrating the pixel and the photo sensor, which are included in the display area shown in FIG. 4 according to some embodiments of the present disclosure. For convenience of description, a pixel PX which is located on an ith horizontal line (or ith pixel row) and is connected to a jth data line Dj is illustrated in FIG. 5. In addition, ith scan lines S1i to S4i (and a jth emission control line Ei) may be included in the scan lines S1 to Sn or the ith scan line Si, shown in FIG. 2.

Referring to FIGS. 1 to 5, a pixel PX and a photo sensor PHS may be disposed on an ith horizontal line.

The pixel PX may include a light emitting element LED and a pixel circuit PXC. In some embodiments, the pixel circuit PXC may include first, second, third, fourth, fifth, sixth, seventh, and eighth transistors T1, T2, T3, T4, T5, T6, T7, and T8 and a storage capacitor Cst.

The first transistor T1 (or driving transistor) may be connected between a first power line PL1 and a first electrode of the light emitting element LED. The first transistor T1 may include a gate electrode connected to a first node N1. The first transistor T1 may control an amount of current (or driving current) flowing from the first power line PL1 to an electrode EP (or power line) via the light emitting element LED, based on a voltage of the first node N1. A first power voltage VDD may be provided to the first power line PL1, and a second power voltage VSS may be provided to the electrode EP. The first power voltage VDD may be set as a voltage higher than the second power voltage VSS.

The second transistor T2 may be connected to a jth data line Dj and a second node N2. A gate electrode of the second transistor T2 may be connected to a 1ith scan line S1i (or first scan line). The second transistor T2 may be turned on when a first scan signal GW[i] (e.g., a first scan signal having a low level) is supplied to the 1ith scan line S1i, to electrically connect the jth data line Dj and the second node N2 to each other. When each of the first transistor T1 and the third transistor T3 is in a turn-on state, the second transistor T2 may transfer a data signal of the jth data line Dj to the first node N1 in response to the first scan signal GW[i].

The third transistor T3 may be connected between the first node N1 and a third node N3. A gate electrode of the third transistor T3 may be connected to a 4ith scan line S4i (or fourth scan line). The third transistor T3 may be turned on when a fourth scan signal GC[i] is supplied to the 4ith scan line S4i. When the third transistor T3 is turned on, the first transistor T1 may be diode-connected.

The fourth transistor T4 may be connected between the first node N1 and a

second power line PL2. A gate electrode of the fourth transistor T4 may be connected to a 2ith scan line S2i (or second scan line). A first initialization power voltage Vint1 may be provided to the second power line PL2. The fourth transistor T4 may be turned on by a second scan signal GI[i] supplied to the 2ith scan line S2i. When the fourth transistor T4 is turned on, the first initialization power voltage Vint1 may be supplied to the first node N1 (i.e., the gate electrode of the first transistor T1).

The fifth transistor T5 may be connected between the first power line PL1 and the second node N2. A gate electrode of the fifth transistor T5 may be connected to an ith emission control line Ei. The sixth transistor T6 may be connected between the third node N3 and the light emitting element LED (or a fourth node N4). A gate electrode of the sixth transistor T6 may be connected to the ith emission control line Ei. The fifth transistor T5 and the sixth transistor T6 may be turned off when an emission control signal EM[i] (e.g., an emission control signal EM[i] having a high level) is supplied to the ith emission control line Ei, and be turned on in other cases.

The seventh transistor T7 may be connected between the first electrode of the light emitting element LED (i.e., the fourth node N4) and a third power line PL3. A gate electrode of the seventh transistor T7 may be connected to a 3ith scan line S3i (or third scan line), A second initialization power voltage Vint2 may be provided to the third power line PL3. The second initialization power voltage Vint2 may be equal to or different from the first initialization power voltage Vint1. The seventh transistor T7 may be turned on by a third scan signal GB[i] supplied to the 3ith scan line S3i, to supply the second initialization power voltage Vint2 to the first electrode of the light emitting element LED.

The eighth transistor T8 may be connected between a fifth power line PL5 and the second node N2. A gate electrode of the eighth transistor T8 may be connected to the 3ith scan line S3i. A common voltage VOBS may be provided to the fifth power line PL5. The eighth transistor T8 may be turned on the third scan signal GB[i] supplied to the 3ith scan line S3i, to supply the common voltage VOBS to the second node N2.

The storage capacitor Cst (or capacitor) may be connected or formed between the first power line PL1 and the first node N1.

The photo sensor PHS may include a sensor circuit SC and a light receiving element LRD. The sensor circuit SC may include ninth, tenth, and eleventh transistors T9, T10, and T11. Also, the photo sensor PHS may further include twelfth and thirteenth transistors T12 and T13. The twelfth and thirteenth transistors T12 and T13 may be included in the sensor circuit SC.

The ninth and eleventh transistors T9 and T11 may be connected in series between the third power PL3 and a kth readout line RXk (k is a natural number).

The ninth transistor T9 (or first sensor transistor) may be connected between the third power line PL3 and the eleventh transistor T11. A gate electrode of the ninth transistor T9 may be connected to a fifth node N5 (or sensor node). The ninth transistor T9 may control a current flowing from the third power line PL3 to the kth readout line RXk through the eleventh transistor T11 in response to a voltage of the fifth node N5.

The tenth transistor T10 (or third sensor transistor) may be connected between a fourth power line PL4 and the fifth node N5. A gate electrode of the tenth transistor T10 may be connected to a reset control line RSTL. A reset voltage VRST may be provided to the fourth power line PL4.

The eleventh transistor T11 (or second sensor transistor) may be connected between the ninth transistor T9 and the kth readout line RXk. A gate electrode of the eleventh transistor T11 may be connected to the 1ith scan line S1i. For example, the gate electrode of the eleventh transistor T11 and the gate electrode of the second transistor T2 may share (e.g., each be connected to) the 1ith scan line S1i.

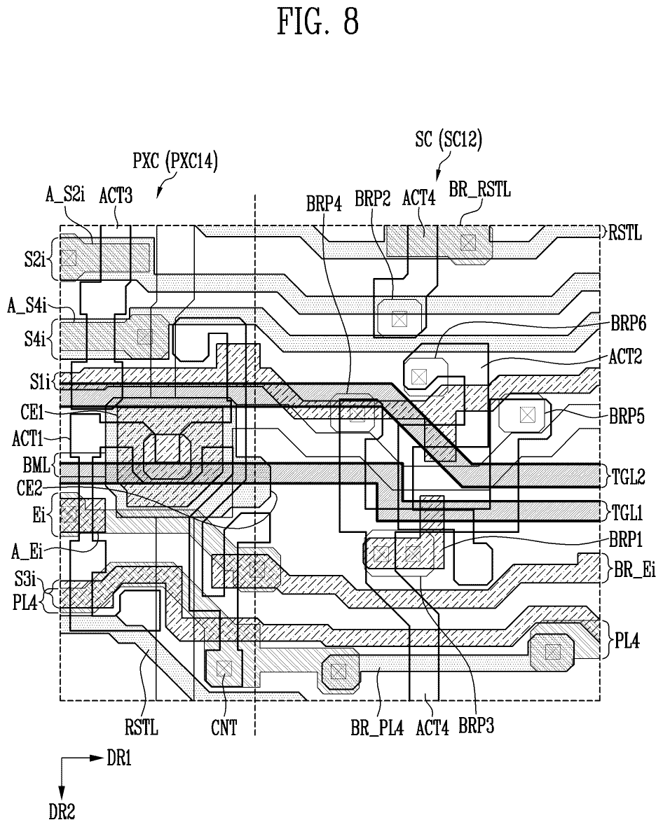

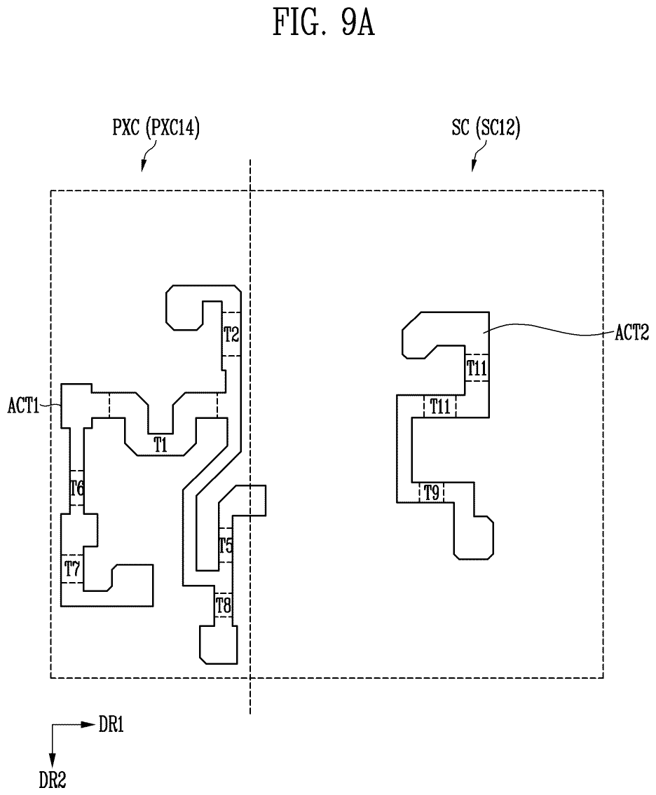

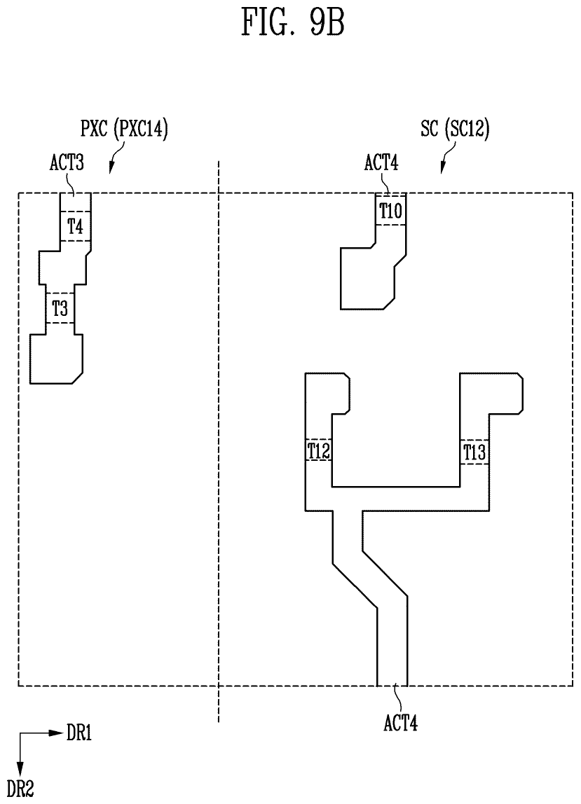

The eleventh transistor T11 may include two sub-transistors connected in series to each other between the ninth transistor T9 and the kth readout line RXk (see, e.g., FIGS. 8 and 9A). For example, the eleventh transistor T11 may be implemented as a dual gate transistor. Thus, current leakage through the eleventh transistor T11 and a sensing error of the sensor circuit SC, which is caused by the current leakage, can be reduced, and the stability of the photo sensor PHS can be improved.

At least one light receiving element LRD may be connected between the fifth node N5 and the electrode EP to which the second power voltage VSS is provided. For example, a first light receiving element LRD1 and a second light receiving element LRD2 may be connected between the fifth node N5 and the electrode EP.

Each light receiving element LRD may generate charges (or current), based on incident light. For example, each light receiving element LRD may perform a function of photoelectric conversion. For example, each light receiving element LRD may be implemented as a photo diode.

The twelfth transistor T12 (or first switching transistor) may be connected between the first light receiving element LRD1 and the fifth node N5. A gate electrode of the twelfth transistor T12 may be connected to a first control line TGL1. The twelfth transistor T12 may be turned on by a first control signal TG1 supplied to the first control line TGL1, to connect the first light receiving element LRD1 to the fifth node N5.

The thirteenth transistor T13 (or second switching transistor) may be connected between the second light receiving element LRD2 and the fifth node N5. A gate electrode of the thirteenth transistor T13 may be connected to a second control line TGL2. The thirteenth transistor T13 may be turned on by a second control signal TG2 supplied to the second control line TGL2, to connect the second light receiving element LRD2 to the fifth node N5.

The photo sensor PHS may further include at least one light receiving element in addition to the first and second light receiving elements LRD1 and LRD2. At least one transistor (i.e., a transistor corresponding to the twelfth and thirteenth transistors T12 and T13) may be further provided to connect the at least one light receiving element to the fifth node N5.

When the tenth transistor T10 is turned on by a reset signal RST supplied to the reset control line RSTL, the reset voltage VRST may be provided to the fifth node N5. For example, the voltage of the fifth node N5 may be reset by the reset voltage VRST. The light receiving element LRD may perform the function of photoelectric conversion from after the reset voltage VRST is applied to the fifth node N5.

The voltage of the fifth node N5 may be changed by an operation of the light receiving element LRD. The voltage of the fifth node N5 (or charges or a current, generated by the light emitting element LRD) may be changed according to an intensity of light incident onto the light receiving element LRD and a time for which the light is incident (or a time for which the light receiving element LRD is exposed to the light).

When the eleventh transistor T11 is turned on by the first scan signal GW[i] supplied to the 1ith scan line S1i, a detection value (current and/or voltage) generated based on the voltage of the fifth node N5 may flow in the kth readout line RXk.

In some embodiments, each of the pixel circuit PXC and the sensor circuit SC may include a p-type transistor and an n-type transistor. In some embodiments, the third transistor T3, the fourth transistor T4, the tenth transistor T10, the twelfth transistor T12, and the thirteenth transistor T13 may be formed with an oxide semiconductor transistor including an oxide semiconductor (or second type semiconductor). For example, the third transistor T3, the fourth transistor T4, the tenth transistor T10, the twelfth transistor T12, and the thirteenth transistor T13 may be formed with an n-type oxide semiconductor transistor, and include an oxide semiconductor layer as an active layer.

The oxide semiconductor transistor can be formed through a low temperature process, and have a charge mobility lower than a charge mobility of a poly-silicon semiconductor transistor. That is, the oxide semiconductor transistor may have a desirable off-current characteristic. Thus, a leakage current in the third transistor T3, the fourth transistor T4, the tenth transistor T10, the twelfth transistor T12, and the thirteenth transistor T13 can be minimized or substantially reduced.

The other transistors (e.g., first, second, fifth, sixth, seventh, eighth, ninth, and eleventh transistors T1, T2, T5, T6, T7, T8, T9, and T11 may be formed with the poly-silicon semiconductor transistor including a silicon semiconductor (or first type semiconductor), and include a poly-silicon semiconductor layer as an active layer. For example, the active layer may be formed through a low-temperature poly-silicon (LTPS) process. For example, the poly-silicon semiconductor transistor may be a p-type poly-silicon transistor. Because the poly-silicon semiconductor transistor has an advantage of high response speed, the poly-silicon semiconductor transistor may be applied to a switching element which requires fast switching.

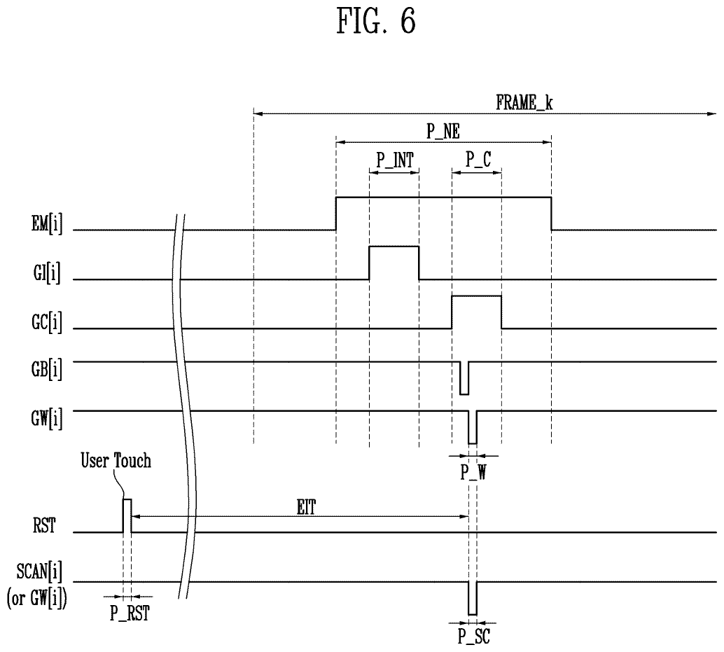

FIG. 6 is a waveform diagram illustrating operations of the pixel and the photo sensor, which are shown in FIG. 5, according to some embodiments of the present disclosure.

Referring to FIGS. 1, 2, 5, and 6, the emission control signal EM[i] may be provided to the ith emission control line Ei, the second scan signal GI[i] may be provided to the 2ith scan line S2i, the fourth scan signal GC[i] may be provided to the 4ith scan line S4i, the third scan signal GB[i] may be provided to the 3ith scan line S3i, and the first scan signal GW[i] may be provided to the 1ith scan signal S1i. The reset signal RST may be provided to the reset control line RSTL. A sensing scan signal SCAN[i] (or ith sensing scan signal) may mean a signal provided to the gate electrode of the eleventh transistor T11. Because the gate electrode of the eleventh transistor T11 may be connected to the 1ith scan line Sli, the sensing scan signal SCAN[i] may be the first scan signal GW[i].

A kth frame period FRAME_k may include a non-emission period P_NE, and the non-emission period P_NE (or the kth frame period FRAME_k) may include an initialization period P_INT, a compensation period P_C, and a writing period P_W. The writing period P_W may be included in the compensation period P_C.

In the non-emission period P_NE, the emission control signal EM[i] may have a high level (or first voltage level). The fifth transistor T5 and the sixth transistor T6 may be turned off in response to the emission control signal EM[i] having the high level, and the pixel PX may not emit light.

In the initialization period P_INT, the second scan signal GI[i] may have the high level. The fourth transistor T4 may be turned on in response to the second scan signal GI[i] having the high level, and the first initialization power voltage Vint1 of the second power line PL2 may be provided to the first node N1 (or the gate electrode of the first transistor T1).

After that, the fourth scan signal GC[i] may have the high level during the compensation period P_C. The third transistor T3 may be turned on in response to the fourth scan signal GC[i] having the high level, and the first transistor T1 may be diode-connected.

In the writing period P_W, the first scan signal GW[i] may have a low level (or second voltage level). The second transistor T2 may be turned on in response to the first scan signal GW[i] having the low level, and a data signal may be provided to the second node N2 from the jth data line Dj. In addition, because the third transistor T3 is in a turn-on state in response to the fourth scan signal GC[i] having the high level, the data signal may be transferred to the first node N1 from the second node N2 through the first transistor T1 and the third transistor T3. Because the first transistor T1 maintains a form in which the first transistor T1 is diode-connected by the turned-on third transistor T3, the voltage of the first node N1 may have a voltage obtained by compensating for a threshold voltage of the first transistor T1 in the data signal.

Before the writing period P_W, the third scan signal GB[i] may have the low level. The seventh transistor T7 may be turned on in response to the third scan signal GB[i] having the low level, and the second initialization power voltage Vint2 may be supplied to the first electrode of the light emitting element LED. In addition, the eighth transistor T8 may be turned on in response to the third scan signal GB[i] having the low level, and the common voltage VOBS may be supplied to the second node N2. The third scan signal GB[i] may be a first scan signal (e.g., GW[i−1]) provided to a previous row, but the present disclosure is not limited thereto.

After that, the non-emission period P_NE is terminated, and the emission control signal EM[i] may have the low level. The fifth transistor T5 and the sixth transistor T6 may be turned on in response to the emission control signal EM[i] having the low level, a current flowing path may be formed from the first power line PL1 to the electrode EP through the fifth transistor T5, the first transistor T1, the sixth transistor T6, and the light emitting element LED, a driving current corresponding to the voltage of the first node N1 (e.g., the data signal) may flow through the light emitting element LED according to an operation of the first transistor T1, and the light emitting element LED may emit light with a luminance corresponding to the driving current.

For example, the reset signal RST may have the high level in a reset period P_RST before the kth frame period FRAME_k. When a touch input of a user or a fingerprint sensing request occurs, the reset circuit 221 (see, e.g., FIG. 2) may provide the reset signal RST having the high level to the reset control line RSTL. The tenth transistor T10 may be turned on in response to the reset signal RST having the high level, and the reset voltage VRST may be applied to the fifth node N5. The voltage of the fifth node N5 may be reset by the reset voltage VRST.

After that, the tenth transistor T10 may be turned off in response to the rest signal RST having the low level. When light is incident onto the light receiving element LRD during an exposure time, the voltage of the fifth node N5 may be changed by a photoelectric conversion function of the light receiving element LRD.

The sensing scan signal SCAN[i], i.e., the first scan signal GW[i] may have the low level in a sensing scan period P_SC of the kth frame period FRAME_k. The sensing scan period P_SC may be the same as the writing period P_W. The eleventh transistor T11 may be turned on in response to the first scan signal GW[i], and a current (or detection value) may flow from the third power line PL3 to the kth readout line RXk, corresponding to the voltage of the fifth node N5.

For example, when the touch input of the user occurs, a current, i.e., a detection value corresponding to light reflected by the user (e.g., a finger of the user) may be output in the kth frame period FRAME_k. For example, a fingerprint of the user may be sensed based on the detection value.

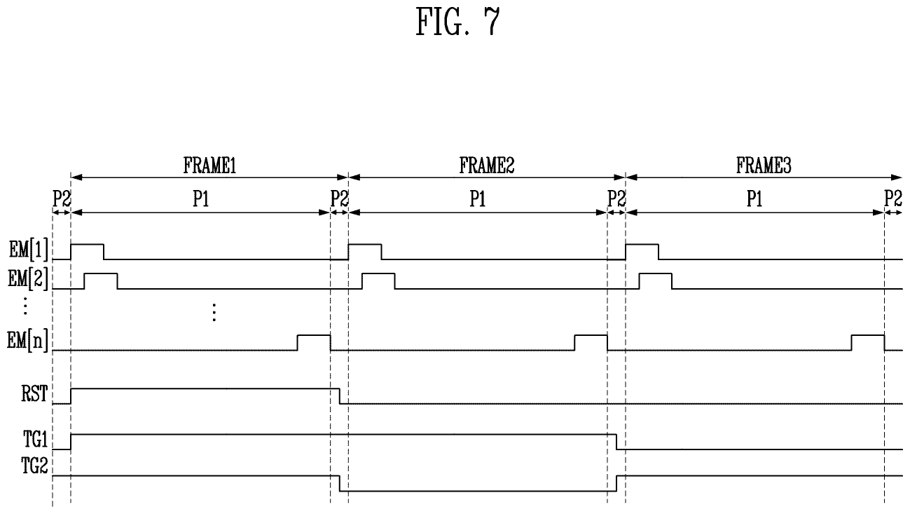

FIG. 7 is a waveform diagram illustrating operations of the pixel and the photo sensor, which are shown in FIG. 5, according to some embodiments of the present disclosure.

Referring to FIGS. 1, 2, 5, 6, and 7, emission control signals EM[1], EM[2], . . . , and EM[n] may be sequentially provided to rows (or pixel rows) in each frame period. The first control signal TG1 may be provided to the first control line TGL1, and the second control signal TG2 may be provided to the second control line TGL2.

Each frame period may include a first period P1 and a second period P2. The first period P1 is an active period, and a valid data signal may be provided or written to the pixel PX. The second period P2 is a blank period between active periods (or frame periods), and the valid data signal is not provided to the pixel PX. The reset signal RST, the first control signal TG1, and the second control signal TG2 may be changed (or toggled) between the high level and the low level in the second period P2, and may be maintained at either the high level or the low level in the first period P1.

Each of the reset signal RST, the first control signal TG1, and the second control signal TG2 may have the high level in a first period P1 of a first frame period FRAME1. Each of the reset signal RST and the first control signal TG1 may be changed from the low level to the high level in a second period P2 just before the first frame period FRAME1. The twelfth transistor T12 may be turned on in response to the first control signal TG1 having the high level, and the first light receiving element LRD1 may be connected to the fifth node N5. Similarly, the thirteenth transistor T13 may be turned on in response to the second control signal TG2 having the high level, and the second light receiving element LRD2 may be connected to the fifth node N5. The tenth transistor T10 may be turned on in response to the reset signal RST having the high level, and the reset voltage VRST may be applied to the fifth node N5. Because the first and second light receiving elements LRD1 and LRD2 are connected to the fifth node N5, the first light receiving element LRD1 and the second light receiving element LRD2 may be reset.

Each of the reset signal RST and the second control signal TG2 may be changed from the high level to the low level in a second period P2 of the first frame period FRAME1. The thirteenth transistor T13 may be turned off in response to the second control signal TG2 having the low level, and the second light receiving element LRD2 may be electrically separated from the fifth node N5. The first light receiving element LRD1 may maintain a state in which the first light receiving element LRD1 is connected to the fifth node N5.

When light is incident onto the first light receiving element LRD1 in a second frame period FRAME2, the voltage of the fifth node N5 may be changed by the photoelectric conversion function of the first light receiving element LRD1. For example, as described with reference to FIG. 6, a current may flow in the kth readout line RXk, corresponding to the voltage of the fifth node N5, in response to the first scan signal GW[i]. For example, an electrical signal, i.e., a sensing signal of light sensed by the first light receiving element LRD1 may be acquired.

The first control signal TG1 may be changed from the high level to the low level in a second period P2 of the second frame period FRAME2. The twelfth transistor T12 may be turned off in response to the first control signal TG1 having the low level, and the first light receiving element LRD1 may be electrically separated from the fifth node N5. In addition, the second control signal TG2 may be changed from the low level to the high level in the second period P2 of the second frame period FRAME2. The thirteenth transistor T13 may be turned on in response to the second control signal TG2 having the high level, and the second light receiving element LRD2 may be connected to the fifth node N5.

Similarly to the second frame period FRAME2, an electrical signal, i.e., a sensing signal of light sensed by the second light emitting element LRD2 may be acquired in a third frame period FRAME3.

As described above, the first light receiving element LRD1 and the second light receiving element LRD2 may be alternately selected using the first control signal TG1 and the second control signal TG2, and a sensing signal may be acquired using each of the first light receiving element LRD1 and the second light receiving element LRD2. Accordingly, a sensing signal and resolution according thereto can be improved, as compared with a case where a sensing signal is acquired concurrently (e.g., simultaneously) using the first light receiving element LRD1 and the second light receiving element LRD2.

Because the reset signal RST, the first control signal TG1, and the second control signal TG2 may be changed between the high level and the low level in only the second period P2 and is maintained at the high level or the low level in the first period P1, the reset signal RST, the first control signal TG1, and the second control signal TG2 may substantially have no influence on operations of the pixel PX (e.g., an initialization operation, a compensation operation, a writing operation, and the like) in the first period P1. Accordingly, a design limitation of the reset signal RSTL, the first control line TGL1, and the second control line TGL2 (e.g., a limitation that the reset signal RSTL, the first control line TGL1, and the second control line TGL2 should be disposed not to be interfered with the operations of the pixel PX) can be reduced, and resolution deterioration or the like, which is caused by the design limitation, can be reduced.

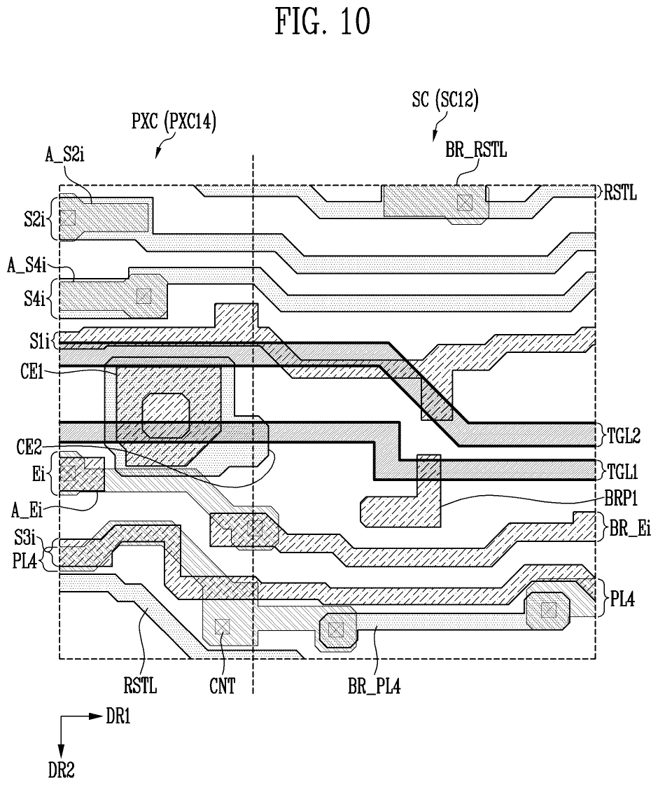

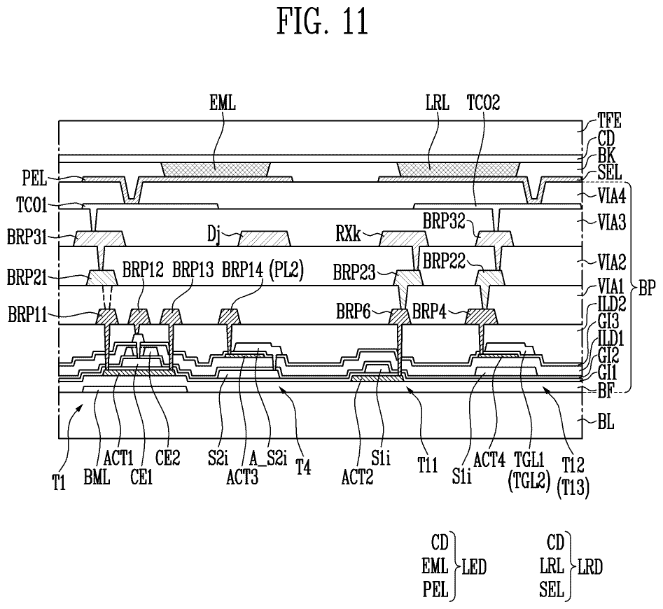

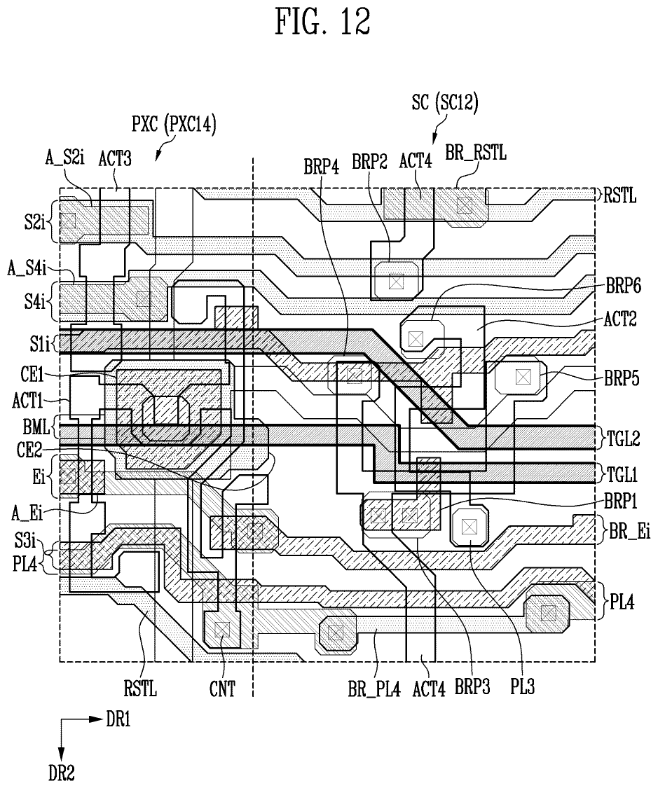

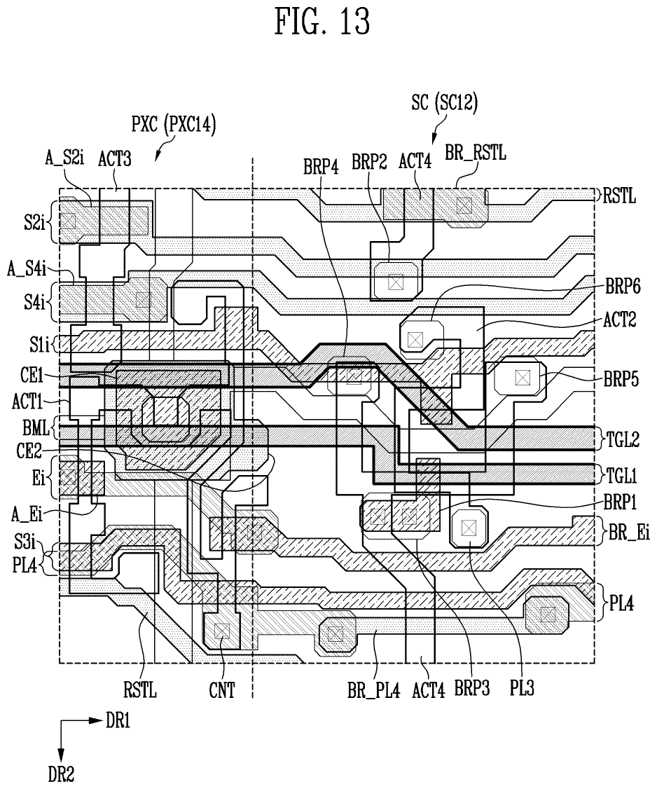

FIGS. 8, 9A, 9B, and 10 are plan views illustrating the display area shown in FIG. 4 according to some embodiments of the present disclosure. In FIG. 8, the pixel circuit PXC and the sensor circuit SC, which are shown in FIG. 5, are illustrated. In FIG. 9A, a first semiconductor layer as a component shown in FIG. 8 is illustrated. In FIG. 9B, a second semiconductor layer as a component shown in FIG. 8. In FIG. 10, the other components are illustrated, except a lower electrode BML and the first and second semiconductor layers. FIG. 11 is a cross-sectional view illustrating the display area shown in FIG. 4 according to some embodiments of the present disclosure. FIGS. 12 and 13 are plan views illustrating the display area shown in FIG. 4 according to some other embodiments of the present disclosure. In FIGS. 12 and 13, various arrangements of the second control line TGL2 are illustrated.

In FIGS. 8 to 13, a sub-pixel is simplified and illustrated, such as that each electrode is illustrated as an electrode having a signal layer and each insulating layer is illustrated as an insulating layer provided as a single layer, but the present disclosure is not limited thereto.

In some embodiments of the present disclosure, “being formed and/or provided in the same layer” may mean being formed through the same process, and “being formed and/or provided in different layers” may mean being formed through different processes.

Referring to FIGS. 4, 5, and 8 to 13, the pixel circuit PXC and the sensor circuit SC may correspond to the fourth pixel circuit PXC14 and the second sensor circuit SC12 of the first pixel row R1 shown in FIG. 4, respectively. Each of the other pixel circuits PXC11 to PXC13 and PXC21 to PXC24 shown in FIG. 4 may be substantially the same as the pixel circuit PXC or be symmetrical to the pixel circuit PXC. In FIG. 11, the first transistor T1, the fourth transistor T4, the eleventh transistor T11, and the twelfth transistor T12 are illustrated. Each of the other transistors T2, T3, T5, T6, T7, T8, T9, and T10 may have a cross-sectional structure substantially identical or similar to the eleventh transistor T11 or the twelfth transistor T12.

Hereinafter, components will be described according to an order in which the components are stacked on a base layer BL, based on FIG. 11.

The base layer BL (or substrate) may be made of an insulative material such as glass or resin. The base layer BL may be made of a material having reflexibility to be curvable or foldable. The base layer BL may have a single-layer structure or a multi-layer structure.

A backplane structure BP including the pixel circuit PXC and the sensor circuit SC may be provided on the base layer BL. The backplane structure BP may include a semiconductor layer, a plurality of conductive layers, and a plurality of insulating layers.

A first conductive layer may be disposed on the base layer BL. The first conductive layer may include a conductive material. For example, the conductive material may include copper (Cu), molybdenum (Mo), tungsten (W), aluminum neodymium (AlNd), titanium (Ti), aluminum (Al), silver (Ag), and/or alloys thereof. The first conductive layer may include the lower electrode BML.

The lower electrode BML may overlap with the first transistor T1 (or a first capacitor electrode CE1 and a second capacitor electrode CE2) on a plane. The lower electrode BML may shield the first transistor T1 (or the first capacitor electrode CE1 and the second capacitor electrode CE2) under the first transistor T1. A constant voltage may be applied to the lower electrode BML. For example, the first power voltage VDD may be applied to the lower electrode BML, but the present disclosure is not limited thereto. The lower electrode BML may extend in the first direction DR1 and the second direction DR2 with respect to the first transistor T1. The lower electrode BML may have a mesh structure throughout the entire display area.

A buffer layer BF may be provided on the base layer BL to cover the lower electrode BML. The buffer layer BF may be an insulating layer including an inorganic material. For example, the inorganic material may include at least one of silicon nitride (SiNₓ), silicon oxide (SiOₓ), silicon oxynitride (SiOₓN_{y}), and a metal oxide such as aluminum oxide (AlOₓ). The buffer layer BF may be provided as a single layer, but be provided as a multi-layer including at least two layers. The buffer layer BF may prevent an impurity from being diffused into a transistor or reduce the likelihood of this occurring.

A first semiconductor layer (or first active layer) may be disposed on the buffer layer BF. The first semiconductor layer may include a first semiconductor pattern ACT1 of the pixel circuit PXC and a second semiconductor pattern ACT2 of the sensor circuit SC. The first semiconductor pattern ACT1 and the second semiconductor pattern ACT2 may be formed of a poly-silicon semiconductor.

The first semiconductor pattern ACT1 overlapping with the first capacitor electrode CE1 may constitute a channel region of the first transistor T1. The first semiconductor pattern ACT1 may extend in the second direction DR2 from both ends of the channel region of the first transistor T1. The first semiconductor pattern ACT1 overlapping with an ith emission control line Ei (or an emission gate electrode A_Ei and an emission bridge pattern BR_Ei) may constitute a channel region of the fifth transistor T5 and a channel region of the sixth transistor T6. The first semiconductor pattern ACT1 may further extend in the second direction DR2 from the channel region of the sixth transistor T6. The first semiconductor pattern ACT1 overlapping with a 3ith scan line S3i may constitute a channel region of the seventh transistor T7. The first semiconductor pattern ACT1 may further extend in the second direction DR2 from the channel region of the fifth transistor T5. The first semiconductor pattern ACT1 overlapping with the 3ith scan line S3i may constitute a channel region of the eighth transistor T8. The first semiconductor pattern ACT1 may extend in the opposite direction of the second direction DR2 from a right end portion of the channel region of the first transistor T1. The first semiconductor layer ACT1 overlapping with a 1ith scan line S1i may constitute a channel region of the second transistor T2.

A channel region is, for example, a semiconductor patten undoped with an impurity, and may be an intrinsic semiconductor. The other region of the semiconductor pattern (e.g., the other region of the first semiconductor pattern ACT1) except the channel region may be a semiconductor pattern doped with the impurity.

The second semiconductor pattern ACT2 may be spaced apart from the first semiconductor pattern ACT1 in the first direction DR1. The second semiconductor pattern ACT2 overlapping with a first bridge pattern BRP1 may constitute a channel region of the ninth transistor T9. The second semiconductor pattern ACT2 overlapping with the 1ith scan line S1i may constitute a channel region of the eleventh transistor T11 (or two sub-transistors).

A first gate insulating layer GI1 (or first insulating layer) may be disposed on the first semiconductor layer. The first gate insulating layer GI1 may be an insulating layer made of an inorganic material.

A second conductive layer may be disposed on the first gate insulating layer GI1. The second conductive layer may include a conductive material. The second conductive layer may include the first capacitor electrode CE1, the first bridge pattern BRP1, the emission gate electrode A_Ei, the emission bridge pattern BR_Ei, the 1ith scan line S1i, and the 3ith scan line S3i. The emission gate electrode A_Ei and the emission bridge pattern BR_Ei may be connected to the ith emission control line Ei which will be described later.

The first capacitor electrode CE1 overlapping with the first semiconductor pattern ACT1 may constitute a gate electrode of the first transistor T1.

The first bridge pattern BRP1 overlapping with the first semiconductor pattern ACT1 may constitute a gate electrode of the ninth transistor T9.

The emission gate electrode A_Ei overlapping with the first semiconductor pattern ACT1 may constitute a gate electrode of the sixth transistor T6.

The 1ith scan line S1i and the emission bridge pattern BR_Ei may be spaced apart from each other with the first capacitor electrode CE1 interposed therebetween. Each of the 1ith scan line S1i, the emission bridge pattern BR_Ei, and the 3ith scan line S3i may roughly extend in the first direction DR1.

The 1ith scan line S1i overlapping with the first semiconductor pattern ACT1 may constitute a gate electrode of the second transistor T2.

The 1ith scan line Sti overlapping with the second semiconductor pattern ACT2 may constitute a gate electrode of the eleventh transistor T11.

The emission bridge pattern BR_Ei overlapping with the first semiconductor pattern ACT1 may constitute a gate electrode of the fifth transistor T5.

The 3ith scan line S3i overlapping with the first semiconductor pattern ACT1 may constitute a gate electrode of the seventh transistor T7 and a gate electrode of the eighth transistor T8.

A second gate insulating layer GI2 (or second insulating layer) may be disposed over the second conductive layer. The second gate insulating layer GI2 may be an insulating layer made of an inorganic material.

A third conductive layer may be disposed on the second gate insulating layer GI2. The third conductive layer may include a conductive material. The third conductive layer may include the second capacitor electrode CE2, a 2ith scan line S2i, a 4ith scan line S4i, a reset control line RSTL, and a fourth power bridge pattern BR_PL4.

The second capacitor electrode CE2 may overlap with the first capacitor electrode CE1, and the first capacitor electrode CE1 and the second capacitor electrode CE2 may form a storage capacitor Cst. Most of the first capacitor electrode CE1 may overlap with the second capacitor electrode CE2. The second capacitor electrode CE2 may include an opening exposing the first capacitor electrode CE1.

On a plane, the 2ith scan line S2i, the 4ith scan line S4i, the reset control line RSTL, and the fourth power bridge pattern BR_PL4 may be spaced apart from each other in the second direction DR2, and each of the 2ith scan line S2i, the 4ith scan line S4i, the reset control line RSTL, and the fourth power bridge pattern BR_PL4 may roughly extend in the first direction DR1.

A first interlayer insulating layer ILD1 (or third insulating layer) may be disposed over the third conductive layer. The first interlayer insulating layer ILD1 may be an insulating layer made of an inorganic material.

A second semiconductor layer (or second active layer) may be disposed on the first interlayer insulating layer ILD1. The second semiconductor layer may include a third semiconductor pattern ACT3 of the pixel circuit PXC and a fourth semiconductor pattern ACT4 of the sensor circuit SC. The third semiconductor pattern ACT3 and the fourth semiconductor pattern ACT4 may be formed of an oxide semiconductor.

The third semiconductor pattern ACT3 overlapping with the 2ith scan line S2i (and a 2ith scan gate electrode A_S2i) may constitute a channel region of the fourth transistor T4. The third semiconductor pattern ACT3 overlapping with the 4ith scan line S4i (and a 4ith scan gate electrode A_S4i) may constitute a channel region of the third transistor T3. The fourth semiconductor pattern ACT4 overlapping with the reset control line RSTL (and a reset bridge pattern BR_RSTL) may constitute a channel region of the tenth transistor T10. The fourth semiconductor pattern ACT4 overlapping with a first control line TGL1 may constitute a channel region of the twelfth transistor T12. The fourth semiconductor pattern ACT4 overlapping with a second control line TGL2 may constitute a channel region of the thirteenth transistor T13.

A third gate insulating layer GI3 (or fourth insulating layer) may be disposed over the second semiconductor layer. The third gate insulating layer GI3 may be an insulating layer made of an inorganic material.

A fourth conductive layer may be disposed on the third gate insulating layer GI3. The fourth conductive layer may include a conductive material. The fourth conductive layer may include the 2ith scan gate electrode A_S2i, the 4ith scan gate electrode A_S4i, the reset bridge pattern BR_RSTL, the ith emission control line Ei, a fourth power line PL4, the first control line TGL1, and the second control line TGL2.

The 2ith scan gate electrode A_S2i may be connected to the 2ith scan line S2i through a contact hole CNT penetrating the third gate insulating layer GI3 and the first interlayer insulating layer ILD1. The 2ith scan gate electrode A_S2i overlapping the third semiconductor pattern ACT3 may constitute a gate electrode of the fourth transistor T4.

The 4ith scan gate electrode A_S4i may be connected to the 4ith scan line S4i through a contact hole CNT. The 4ith scan gate electrode A_S4i overlapping with the third semiconductor pattern ACT3 may constitute a gate electrode of the third transistor T3.

The reset bridge pattern BR_RSTL may be connected to the reset control line RSTL through a contact hole CNT. The reset bridge pattern BR_RSTL overlapping with the fourth active pattern ACT4 may constitute a gate electrode of the tenth transistor T10.

The ith emission control line Ei may be connected to the emission gate electrode A_Ei and the emission bridge pattern BR_Ei through a contact hole CNT.

The fourth power line PL4 may be connected to the fourth power bridge pattern BR_PL4 through a contact hole CNT. Also, the fourth power line PL4 may be connected to the first semiconductor pattern ACT1 through a contact hole CNT.

Each of the first control line TGL1 and the second control line TGL2 may roughly extend in the first direction DR1. The first control line TGL1 and the second control line TGL2 may extend while transversing the pixel circuit PXC (or pixel).

The first control line TGL1 overlapping with the fourth semiconductor pattern ACT4 may constitute a gate electrode of the twelfth transistor T12.

The second control line TGL2 overlapping with the fourth semiconductor pattern ACT4 may constitute a gate electrode of the thirteenth transistor T13.

In some embodiments, at least one of the first and second control lines TGL1 and TGL2 may overlap with at least one of the first transistor T1 and the storage capacitor Cst.

In some embodiments, a partial section of at least one of the first and second control lines TGL1 and TGL2 may overlap with about 50% or more of the storage capacitor Cst in the second direction DR2. In some embodiments, a partial section of at least one of the first and second control lines TGL1 and TGL2 may completely overlap with the storage capacitor Cst in the second direction DR2.

An example will be described with reference to FIGS. 8 and 10. The first control line TGL1 may transverse the first and second capacitor electrodes CE1 and CE2 of the storage capacitor Cst in the first direction DR1, and completely overlap with the first and second capacitor electrodes CE1 and CE2 of the storage capacitor Cst. As shown in FIGS. 8 and 10, the second control line TGL2 may partially overlap with the second capacitor electrode CE2 of the storage capacitor Cst in the second direction DR2.

An example will be described with reference to FIG. 12. The second control line TGL2 may not overlap with the storage capacitor Cst. An example will be described with reference to FIG. 13. The second control line TGL2 may completely overlap with the first and second capacitor electrodes CE1 and CE2 of the storage capacitor Cst. Similarly to the second control line TGL2 shown in FIGS. 12 and 13, the arrangement of the first control line TGL1 may be changed to partially overlap with the storage capacitor Cst or not to overlap with the storage capacitor Cst.

In some embodiments wherein the first and second control lines TGL1 and TGL2 overlaps with the second capacitor electrode CE2 of the storage capacitor Cst, only the first interlayer insulating layer ILD1 and the third gate insulating layer GI3 may be disposed between the first and second control lines TGL1 and TGL2 and the second capacitor electrode CE2. If the third gate insulating layer GI3 is not entirely disposed on the base layer BL but locally disposed on only the second semiconductor layer (e.g., the fourth semiconductor pattern ACT4), only the first interlayer insulating layer ILD1 may be disposed between the first and second control lines TGL1 and TGL2 and the second capacitor electrode CE2. For example, only two or fewer insulating layers may be disposed between the first and second control lines TGL1 and TGL2 and the second capacitor electrode CE2. Similarly, if the first control line TGL1 overlaps with the 1ith scan line S1i, three or fewer insulating layers may be disposed between the first control line TGL1 and the 1ith scan line S1i.

The first and second control lines TGL1 and TGL2 and the second capacitor electrode CE2 of the storage capacitor Cst may be coupled, and the first and second control signals TG1 and TG2 (see, e.g., FIG. 7) applied to the first and second control lines TGL1 and TGL2 may have influence on the storage capacitor Cst and the first transistor T1. By considering this, the first and second control lines TGL1 and TGL2 are to be disposed not to overlap with a lower conductive layer (e.g., scan lines disposed in the second conductive layer and the third conductive layer, and the storage capacitor Cst). Accordingly, the area of the pixel circuit PXC and the sensor circuit SC may be increased, and resolution may be lowered.

However, as described with reference to FIG. 7, because the first and second control signals TG1 and TG2 are not changed but substantially have a constant voltage in the first period P1 (i.e., the active period), the first and second control signals TG1 and TG2 in accordance with some embodiments of the present disclosure do not substantially have no influence (e.g., may have some influence) on the storage capacitor Cst and the first transistor T1. As compared with a case where the first and second control lines TGL1 and TGL2 do not overlap with the first transistor T1, even when the first and second control signals TG1 and TG2 in accordance with some embodiments of the present disclosure overlap with 50% or more of the first transistor T1 (particularly, even when the first and second control signals TG1 and TG2 overlap with 100% of the first transistor T1), a threshold voltage of the first transistor T1 may be changed to about 7% or less, and a turn-on current of the first transistor T1 may be changed to about 2.5% or less. Thus, the first and second control lines TGL1 and TGL2 can be disposed in a form free from the fourth conductive layer closest to the second semiconductor layer (or the fourth semiconductor pattern ACT4), regardless of the lower conductive layer (e.g., the scan lines disposed in the second conductive layer and the third conductive layer, and the storage capacitor Cst).

In some embodiments, a partial section of at least one of the first and second control lines TGL1 and TGL2 may partially overlap with the 1ith scan line S1i in the second direction DR2. In some embodiments, a partial section of at least one of the first and second control lines TGL1 and TGL2 may completely overlap with the 1ith scan line S1i in the second direction DR2.

An example will be described with reference to FIGS. 8 and 10. The second control line TGL2 may partially overlap with the 1ith scan line S1i in the second direction DR2. An example will be described with reference to FIG. 12. The second control line TGL2 may completely overlap with the 1ith scan line S1i in the second direction DR2.

Referring back to FIG. 11, a second interlayer insulating layer ILD2 may be disposed over the fourth conductive layer. The second interlayer insulating layer ILD2 may be an insulating layer made of an inorganic material, but the present disclosure is not limited thereto.

A fifth conductive layer may be disposed on the second interlayer insulating layer ILD2. The fifth conductive layer may include a conductive material. The fifth conductive layer may include a second bridge pattern BRP2, a third bridge pattern BRP3, a fourth bridge pattern BRP4, a fifth bridge pattern BRP5, and a sixth bridge pattern BRP6, which are shown in FIG. 8.

The second bridge pattern BRP2 may be connected to the fourth semiconductor pattern ACT4 through a contact hole CH. The second bridge pattern BRP2 may be connected to the fourth power line PL4 through other bridge patterns.

The third bridge pattern BRP3 may be connected to the fourth semiconductor pattern ACT4 and the first bridge pattern BRP1 through a contact hole CH. The third bridge pattern BRP3 may constitute the fifth node N5 shown in FIG. 5.

The fourth bridge pattern BRP4 may be connected to the fourth semiconductor pattern ACT4 through a contact hole CH. The fourth bridge pattern BRP4 may be connected to a light receiving element LRD (or first light receiving element LRD1 (see FIG. 5)) through a twenty-second bridge pattern BRP22, a thirty-second bridge pattern BRP32, and a second connection electrode TCO2, which are shown in FIG. 11. That is, the fourth bridge pattern BRP4 may connect the twelfth transistor T12 to the first light receiving element LRD1.

The fifth bridge pattern BRP5 may be connected to the fourth semiconductor pattern ACT4 through a contact hole. Similarly to the fourth bridge pattern BRP4, the fifth bridge pattern BRP5 may connect the thirteenth transistor T13 to a second light receiving element LRD2 (see FIG. 5).

The sixth bridge pattern BRP6 may be connected to the second semiconductor pattern ACT2 through a contact hole. The sixth bridge pattern BRP6 may be connected to a kth readout line RXk through a twenty-third bridge pattern BRP23 shown in FIG. 11. That is, the sixth bridge pattern BRP6 may connect the eleventh transistor T11 to the kth readout line RXk.

In addition, the fifth conductive layer may further include an eleventh bridge pattern BRP11, a twelfth bridge pattern BRP12, a thirteenth bridge pattern BRP13, and a fourteenth bridge pattern BRP14 (or a second power line PL2). The eleventh bridge pattern BRP11 may constitute a source electrode of the first transistor T1. The eleventh bridge pattern BRP11 may be connected to a light emitting element LED through a twenty-first bridge pattern BRP21, a thirty-first bridge pattern BRP31, and a first connection electrode TCO1, which are shown in FIG. 11. The twelfth bridge pattern BRP12 may be connected to the gate electrode of the first transistor T1, and the thirteenth bridge pattern BRP13 may constitute a drain electrode of the first transistor T1. The fourteenth bridge pattern BRP14 may constitute one electrode of the fourth transistor T4, and be connected to the second power line PL2.

At least one via layer may be disposed over the fifth conductive layer. For example, a first via layer VIA1, a second via layer VIA2, a third via layer VIA3, and a fourth via layer VIA4 may be sequentially disposed over the fifth conductive layer. Each of the first via layer VIA1, the second via layer VIA2, the third via layer VIA3, and the fourth via layer VIA4 may be an insulating layer made of an inorganic material or an organic material. For example, the organic material may include acrylic resin, epoxy resin, phenolic resin, polyamide resin, polyimide resin, and/or the like. A jth data line Dj and the kth readout line RXk may be disposed between the second via layer VIA2 and the third via layer VIA3. The first connection electrode TCO1 and the second connection electrode TCO2 may be disposed between the third via layer VIA3 and the fourth via layer VIA4. The first connection electrode TCO1 may extend from the thirty-first bridge pattern BRP31 to the light emitting element LED (e.g., a fourth light emitting element (see FIG. 4)), to connect the thirty-first bridge pattern BRP31 and the light emitting element LED to each other. Similarly, the second connection electrode TCO2 may extend from the thirty-second bridge pattern BRP32 to the light receiving element LRD (e.g., the first light receiving element LRD1 or the second light receiving element LRD2, which is shown in FIG. 4), to connect the thirty-second bridge pattern BRP32 and the light receiving element LRD to each other.

A pixel layer including a pixel electrode PEL, a sensor electrode SEL, and a bank layer BK may be provided on the fourth via layer VIA4.

The pixel layer may include the light emitting element LED connected to the pixel circuit PXC and the light receiving element LRD connected to the sensor circuit SC.

In some embodiments, the light emitting element LED may include the pixel electrode PEL, a light emitting layer EML, and a common electrode CD. In some embodiments, the light receiving element LRD may include the sensor electrode SEL, a light receiving layer LRL, and the common electrode CD.

In some embodiments, the pixel electrode PEL and the sensor electrode SEL may be made of a metal layer, such as silver (Ag), magnesium (Mg), aluminum (Al), platinum (Pt), palladium (Pd), gold (Au), nickel (Ni), neodymium (Nd), iridium (Ir), chromium (Cir), or any alloy thereof, and/or indium tin oxide (ITO), indium zinc oxide (IZO), zinc oxide (ZnO), or indium tin zinc oxide (ITZO). The pixel electrode PEL and the sensor electrode SEL may be concurrently (e.g., simultaneously) formed through patterning using a mask.

The bank layer BK (or pixel defining layer) partitioning an emission area and a light receiving area may be provided on the fourth via layer VIA4 on which the pixel electrode PEL and the sensor electrode SEL are formed. The bank layer BK may include openings corresponding to the emission area and the light receiving area. The bank layer BK may be an insulating layer made of an organic material.

In some embodiments, the bank layer BK may include a light absorption material or have a light absorber coated thereon, to absorb light introduced from the outside. For example, the bank layer BK may include a carbon-based black pigment. However, the present disclosure is not limited thereto, and the bank layer BK May include an opaque metal material, such as chromium (Cr), molybdenum (Mo), any alloy of molybdenum and titanium (MoTi), tungsten (W), vanadium (V), niobium (Nb), tantalum (Ta), manganese (Mn), cobalt (Co) or nickel (Ni), which has a suitably high absorption rate.

The light emitting layer EML may be provided on a top surface of the pixel electrode PEL exposed by the bank layer BK, and the light receiving layer LRL may be provided on a top surface of the sensor electrode SEL exposed by the bank layer BK. In some embodiments, the light emitting layer EML may be configured as an organic light emitting layer. The light emitting layer EML may emit light such as red light, green light, or blue light according to an organic material included in the light emitting layer EML. The light receiving layer LRL may emit electrons, corresponding to light in a specific wavelength band, thereby sensing an intensity of the light.

The common electrode CD may be provided on the light emitting layer EML and the light receiving layer LRL. The second power voltage VSS may be supplied to the common electrode CD. The common electrode CD may be made of a metal layer such as silver (Ag), magnesium (Mg), aluminum (Al), platinum (Pt), palladium (Pd), gold (Au), nickel (Ni), neodymium (Nd), iridium (Ir), chromium (Cir), or any alloy thereof, and/or ITO, IZO, ZnO, or ITZO.

An encapsulation layer TFE may be provided over the common electrode CD. The encapsulation layer TFE may be provided as a single layer, but be provided as a multi-layer. In some embodiments, the encapsulation layer TFE may have a stacked structure in which an inorganic material, an organic material, and an inorganic material are sequentially stacked. An uppermost layer of the encapsulation layer TFE may be formed of an inorganic material.

As described above, the first and second control lines TGL1 and TGL2 can be disposed in a form free from the fourth conductive layer closest to the second semiconductor layer (or the fourth semiconductor pattern ACT4), regardless of the lower conductive layer (e.g., the scan lines disposed in the second conductive layer and the third conductive layer, and the storage capacitor Cst). Thus, the area of the pixel circuit PXC and the sensor circuit SC can be decreased, and the resolution can be improved.

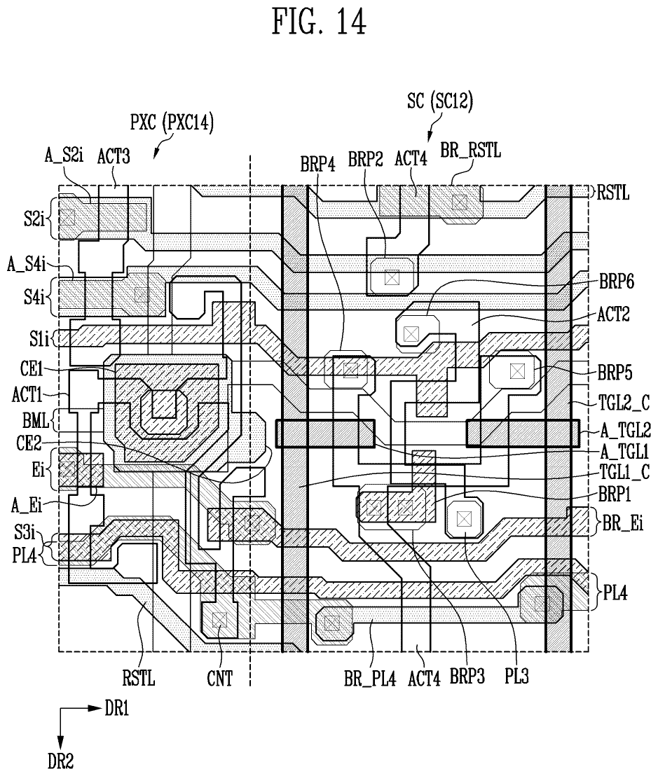

FIG. 14 is a plan view illustrating the display area shown in FIG. 4 according

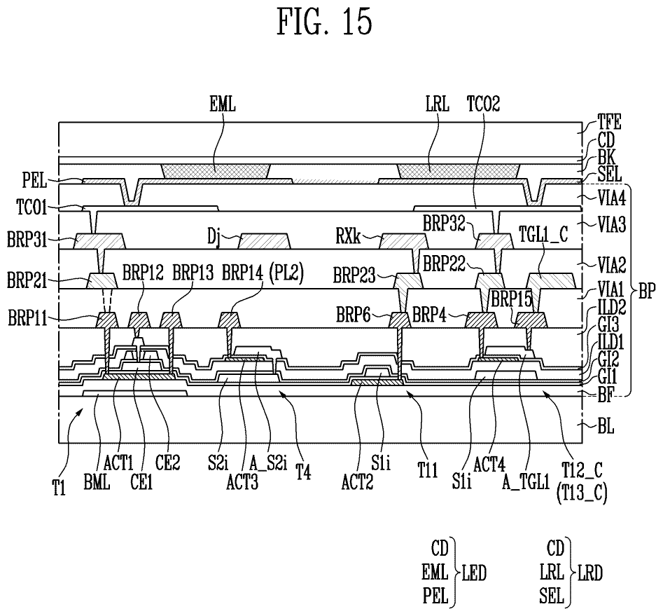

to still some other embodiments of the present disclosure. In FIG. 14, the pixel circuit PXC and the sensor circuit SC, which are shown in FIG. 5, are illustrated. FIG. 15 is a cross-sectional view illustrating the display area shown in FIG. 4 according to still some other embodiments of the present disclosure.

Referring to FIGS. 8, 11, 14, and 15, the embodiment shown in FIGS. 14 and 15 may be substantially identical or similar to the embodiment shown in FIGS. 8 and 11, except first and second control lines TGL1_C and TGL2_C and first and second gate electrodes A_TGL1 and A_TGL2. Therefore, overlapping descriptions will be omitted.

The first gate electrode A_TGL1 and the second gate electrode A_TGL2 may be disposed on the third gate insulating layer GI3.

The first gate electrode A_TGL1 may overlap with the fourth semiconductor pattern ACT4, and constitute a gate electrode of a twelfth transistor T12_C.

The second gate electrode A_TGL2 may overlap with the fourth semiconductor pattern ACT4, and constitute a gate electrode of a thirteenth transistor T13_C.

The first control line TGL1_C and the second control line TGL2_C may be disposed on the first via layer VIA1. Each of the first control line TGL1_C and the second control line TGL2_C may roughly extend in the second direction DR2. The first control line TGL1_C and the second control line TGL2_C may not overlap with the pixel circuit PXC.

The first control line TGL1_C may be connected to the first gate electrode A_TGL1 through a contact hole and a fifteenth bridge pattern BRP15 (see, e.g., FIG. 15). Similarly, the second control line TGL2_C may be connected to the second gate electrode A_TGL2.

In order not to be coupled to components of the pixel circuit PXC, the first control line TGL1_C and the second control line TGL2_C may extend in the second direction DR2, be disposed on the first via layer VIA1 instead of the third gate insulating layer GI3, and be respectively connected to the first gate electrode A_TGL1 and the second gate electrode A_TGL2 through a bridge pattern. However, the opening ratio of the via layer may be lowered by the first control line TGL1_C and the second control line TGL2_C, and the first control line TGL1_C and the second control line TGL2_C may be weak to pixel shrinkage.

Thus, as described with reference to FIGS. 7 to 13, in the display device in accordance with the embodiments of the present disclosure, the first and second control signals TG1 and TG2 are changed or toggled in only the second period P2 (i.e., the blank period), and the first and second control lines TGL1 and TGL2 are disposed in a form free from the fourth conductive layer closest to the second semiconductor layer (or the fourth semiconductor pattern ACT4) (i.e., a design limitation is minimized or substantially reduced). Accordingly, the opening ratio of the via layer can be secured.

A display device according to an embodiment is applicable to various types of electronic devices. In an embodiment, an electronic device includes the above-described display device and may further include other modules or devices having additional functions in addition to the display device.

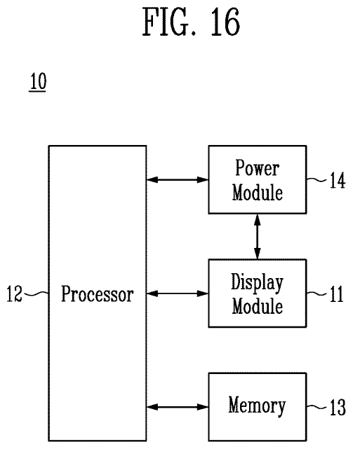

FIG. 16 is a block diagram of an electronic device according to some embodiments of the present disclosure. Referring to FIG. 16, the electronic device 10 may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data and/or information used to operate the processor 12 or the display module 11. When the processor 12 executes an application stored in the memory 13, image data signals and/or input control signals may be transferred to the display module 11. The display module 11 may process the provided signals and output image information on a display screen.

The power module 14 may include a power supply module, such as a power adapter or a battery device, and a power conversion module. The power conversion module converts power supplied by the power supply module and generates power to operate the electronic device 10.

At least one of the above-described components of the electronic device 10 may be included in the display device according to embodiments as described above. In addition, in terms of functionality, some of the individual modules included in one module may be included in the display device and others may be provided separately from the display device. For example, the display module 11 is included in the display device, whereas the processor 12, the memory 13, and the power module 14 are not included in the display device and are instead provided separately in the electronic device 10.

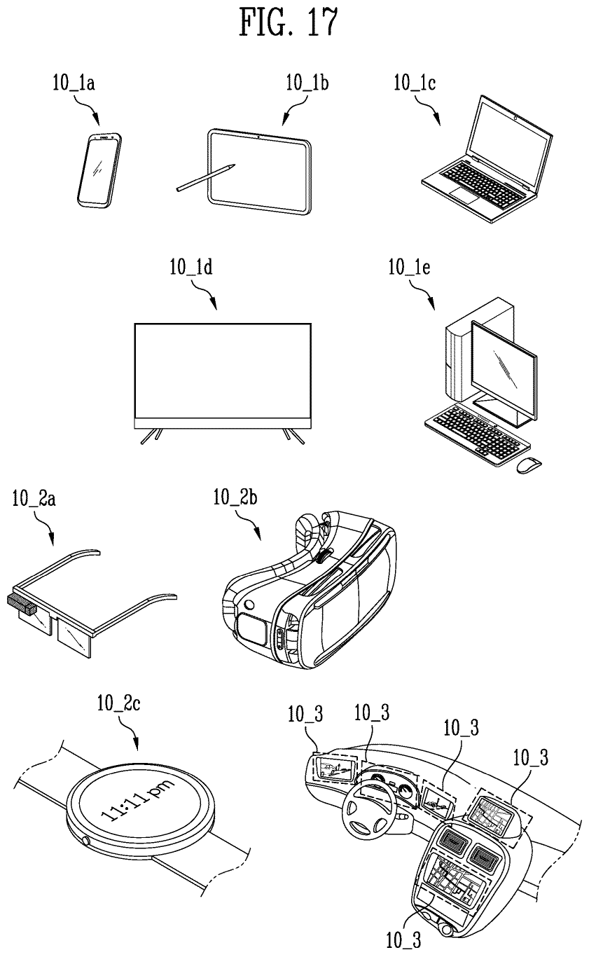

FIG. 17 shows schematic views of various embodiments of an electronic device.

Referring to FIG. 17, various types of electronic devices to which embodiments of a display device are applied may include an electronic device to display images such as a smartphone 10_1a, a tablet PC 10_1b, a laptop computer 10_1c, a television (TV) 10_1d, and a desktop monitor 10_1e, a wearable electronic device including a display module such as smart glasses 10_2a, a head-mounted display (HMD) 10_2b, and a smart watch 10_2c, and an automotive electronic device 10_3 including a display module such as a center information display (CID) disposed at the instrument cluster, the center fascia, and the dashboard of a vehicle, and a room mirror display.

In the display device and the electronic device in accordance with the present disclosure, first and second control lines can be disposed in a form free from a conductive layer closest to a corresponding semiconductor layer, regardless of the arrangement of a component of a pixel circuit. Thus, the area of a pixel and a sensor can be decreased, and resolution can be improved.

It should be understood that embodiments described herein should be considered in a descriptive sense and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims and equivalents thereof.

What is claimed is:

1. A display device comprising:
a pixel comprising a pixel circuit and a light emitting element connected to the pixel circuit, the pixel circuit comprising a first transistor and a capacitor;
a sensor comprising a sensor circuit, light receiving elements, and switching transistors connecting the light receiving elements to the sensor circuit, the sensor circuit comprising a sensor transistor; and
control lines configured to control operations of the switching transistors, at least one of the control lines overlapping with at least one of the first transistor and the capacitor in a plan view.

2. The display device of claim 1, wherein the control lines extend in a first direction while transversing the pixel.

3. The display device of claim 1, wherein the capacitor comprises a capacitor electrode, and
wherein two or less insulating layers are interposed between the capacitor electrode and the control lines in a cross-sectional view.

4. The display device of claim 3, wherein, in a plan view, a partial section of at least one of the control lines overlaps with about 50% or more of the capacitor in a second direction, and the control lines roughly extend in a first direction, and
wherein the second direction is perpendicular to the first direction.

5. The display device of claim 4, wherein, in a plan view, the partial section of the at least one of the control lines completely overlaps with the capacitor in the second direction.

6. The display device of claim 1, wherein the switching transistors comprise a first switching transistor configured to connect a first light receiving element to the sensor circuit in response to a first control signal of a first control line, and a second switching transistor configured to connect a second light receiving element to the sensor circuit in response to a second control signal of a second control line, and
wherein the first control line overlaps with the capacitor.

7. The display device of claim 6, wherein, in a plan view, the first control line transverses the capacitor.

8. The display device of claim 7, wherein the second control line overlaps with an edge portion of the capacitor.

9. The display device of claim 8, further comprising:
a data line configured to transmit a data signal; and
a scan line configured to transmit a scan signal,
wherein the pixel circuit further comprises a second transistor configured to transfer the data signal to the first transistor in response to the scan signal, and
wherein the first control line overlaps with the scan line.

10. The display device of claim 6, wherein the second control line does not overlap with the capacitor.

11. The display device of claim 10, further comprising:
a data line configured to transmit a data signal; and
a scan line configured to transmit a scan signal,
wherein the pixel circuit further comprises a second transistor configured to transfer the data signal to the first transistor in response to the scan signal, and
wherein the first control line overlaps with the scan line.

12. The display device of claim 1, wherein the switching transistors comprise a first switching transistor configured to connect a first light receiving element to the sensor circuit in response to a first control signal of a first control line, and a second switching transistor configured to connect a second light receiving element to the sensor circuit in response to a second control signal of a second control line, and
wherein, in a plan view, the first control line and the second control line transverse the capacitor.

13. The display device of claim 1, wherein control signals applied to the control lines change between a first voltage level and a second voltage level in only a blank period, and have either the first voltage level or the second voltage level in an active period, and
wherein a valid data signal is provided to the pixel in the active period, and the valid data signal is not provided to the pixel in the blank period.

14. The display device of claim 1, further comprising a plurality of sensors comprising the sensor,
wherein the control lines are commonly connected to all of the plurality of sensors.

15. The display device of claim 1, wherein the first transistor of the pixel comprises a silicon semiconductor, and the switching transistors of the sensor comprise an oxide semiconductor.

16. The display device of claim 1, wherein the light emitting element and the light receiving element are at the same layer.

17. A display device comprising:
a pixel comprising a pixel circuit and a light emitting element connected to the pixel circuit, the pixel circuit comprising a first transistor;
a sensor comprising a sensor circuit, a light receiving element, and a switching transistor connecting the light receiving element to the sensor circuit, the sensor circuit comprising a sensor transistor;
a scan line configured to control an operation of the first transistor; and
a control line configured to control an operation of the switching transistor,
wherein, in a plan view, the control line extends while transversing the pixel circuit, and overlaps with the scan line.

18. The display device of claim 17, wherein, in a cross-sectional view, three or fewer insulating layers are interposed between the scan line and the control line.

19. The display device of claim 17, wherein a control signal applied to the control line changes between a first voltage level and a second voltage level in only a blank period, and has either the first voltage level or the second voltage level in an active period, and
wherein a valid data signal is provided to the pixel in the active period, and the valid data signal is not provided to the pixel in the blank period.

20. An electronic device comprising:
a display device configured to display an image, based on input image data; and
a processor configured to provide the input image data to the display device,
wherein the display device comprises:
a pixel comprising a pixel circuit and a light emitting element connected to the pixel circuit, the pixel circuit comprising a first transistor and a capacitor;
a sensor comprising a sensor circuit, light receiving elements, and switching transistors connecting the light receiving elements to the sensor circuit, the sensor circuit comprising a sensor transistor; and
control lines controlling operations of the switching transistors, and
wherein, in a plan view, at least one of the control lines overlaps with at least one of the first transistor and the capacitor.
